(19) United States
(12) Patent Application Publication
(10) Pub. No.: US 2024/0006301 A1
(43) Pub. Date: Jan. 4, 2024

(54) SEMICONDUCTOR PACKAGE

(71) Applicants: nD-HI Technologies Lab, Inc., TAIPEI CITY (TW); ETRON TECHNOLOGY, INC., HSINCHU (TW)

(72) Inventors: HO-MING TONG, TAIPEI CITY (TW); CHAO-CHUN LU, HSINCHU (TW)

(21) Appl. No.: 18/345,611

(22) Filed: Jun. 30, 2023

Related U.S. Application Data
(60) Provisional application No. 63/357,059, filed on Jun. 30, 2022.

(51) Int. Cl. H01L 23/498; H01L 23/00; H01L 21/48; H01L 25/10

(52) U.S. Cl. CPC H01L 23/49894; H01L 23/49827; H01L 24/05; H01L 24/08; H01L 24/80; H01L 21/486; H01L 23/49838; H01L 25/105; H01L 2224/05647; H01L 2224/05571; H01L 2224/05573; H01L 2224/08237; H01L 2224/80896; H01L 2224/80357; H01L 2224/80379; H01L 2224/80486; H01L 2924/05442; H01L 2924/05042; H01L 2224/80447; H01L 2224/80012; H01L 24/16; H01L 2224/16227; H01L 2224/08145; H01L 23/481

(57) ABSTRACT

A semiconductor package is provided. The semiconductor package includes an integrated circuit (IC) block and a first substrate. The IC block has a first interconnect layer. The first substrate carries the IC block. The first substrate includes a second interconnect layer facing the first interconnect layer and a third interconnect layer opposite to the second interconnect layer. Furthermore, at least one of the second interconnect layer or the third interconnect layer is composed of a dielectric material and a conductive material substantially identical to a corresponding dielectric material and a corresponding conductive material of the first interconnect layer.

### PRIORITY CLAIM AND CROSS-REFERENCE

This application claims the benefit of prior-filed U.S. provisional application No. 63/357,059, filed on Jun. 30, 2022, and incorporates by reference herein in its entirety.

### FIELD

The disclosure relates in general to semiconductor packages, and more particularly to semiconductor packages configured to speed up interconnect scaling for 3D ICs and advanced System-in-a-Packages (SiPs).

### BACKGROUND

2D geometrical scaling of conventional transistors is fast approaching “red brick wall” despite most recent evolutions attributable to the great feats of engineering and material science involving extremely complex multiple-step lithographic patterning, new strain enhancing materials and metal oxide gate. 3D IC (3D integrated circuit) integration represents a radical departure from traditional 2D IC and 2D package integration by vertical stacking of ICs and/or transistor layers on an IC, an interposer or a substrate to provide extremely dense ICs. 3D ICs have been recognized as a next generation semiconductor technology, which has the advantage of high performance, low power consumption, small physical size and high integration density. 3D ICs provide a path to continue to meet the performance/cost demands of next generation devices while remaining at more relaxed gate lengths with less process complexity. Commercial applications of 3D IC include primarily of high-bandwidth memory (HBM) and hybrid memory cube which are 3D memory stacks on base dies, as illustrated by 906 in FIG. 1.

More recently, cache on logic/processor IC has also been demonstrated. Going forward, the number of 3D IC applications will steadily increase. 3D ICs are expected to find broad based utilities in applications such as high-performance computing (HPC), data centers, AI (artificial intelligence)/ML (machine learning), 5G/6G networks, graphics, smart phones/wearables, automotive and others that demand “extreme,” ultra-high-performance, higher-power-efficiency devices. These devices include CPU (central processing unit), GPU (graphics processing unit), FPGA (field-programmable gate array), ASIC (application specific IC), TPU (tensor processing unit), integrated photonics, AP (application processor for cell phones), and packet buffer/router devices.

Commercial 3D ICs such as a 3D HBM DRAM memory die stack on logic are increasingly being adopted by commercial 2.5D IC structures that contain through silicon vias (TSVs), in both active memory and logic dies and in the silicon interposer. 3D ICs can enable memory on memory, memory over logic, logic over logic using interconnect technologies such as TSV, redistribution layers (RDL) containing interconnect wiring and micro-vias, copper pillar micro-bumps/solder bumps, and flip chip bonding or the emerging copper hybrid bonding first proven by Sony for complementary metal-oxide semiconductor (CMOS) image sensors for inter-die communication. 3D ICs allow for vertical stacking of heterogeneous dies from different manufacturing processes and nodes, chip reuse and chiplets-in-SiP (system-in-a-package) for high-performance applications already pushing the limits of a single die at the most advanced node. Monolithic 3D ICs build on multiple active silicon layers with vertical interconnects between layers. It is still in the early development stage and is not widely deployed yet.

To accelerate adoption, 3D IC systems must be architected in a more holistic way via IC-package-system co-design which involves the silicon IP, ICs/chiplets and IC package and which addresses accompanying power and thermal challenges. In contrast to PPAC (performance, power, area and cost) optimization per “square centimeter” for 2D packaging, IC-package-system co-design for 3D ICs aims to achieve PPAC optimization per “cubic millimeter” wherein the vertical dimension that covers ICs, interposer, IC package substrate, IC package and system printed circuit board (PCB) must now be considered in all tradeoff decisions. 3D ICs often contain the most advanced ICs the industry has to offer. Advanced ICs today can contain hundreds of billions of transistors which are fabricated by the front-end-of-the-line (FEOL) processes and interconnected by sometimes over 30 miles of interconnect within multiple levels (10 or more layers) of vertical interconnects built by the back-end-of-the-line (BEOL) SiO₂/Cu (silicon dioxide/copper) and low-x dielectrics (x=relative dielectric constant)/Cu RDL processes. Lower-level interconnects or lines connecting the tiny and closely packed transistors are called local interconnects (LCs) which are usually thin and short in length. Global interconnects (GCs) which are higher up in the IC BEOL structure travel between different circuit blocks and are typically thick, long and widely separated. Vias or connections between interconnect wiring layers allow signals and power to be transmitted from one layer to the next. Beyond the IC levels (and as can be seen in FIG. 1), advanced memory and logic ICs are typically interconnected through the PI/Cu (polyimide/Cu) interconnect wiring/micro-via layers in the RDL on the interposer, copper TSVs in the interposer and active dies, and flip chip bonding based on copper pillar micro-bumps on the active dies. The interposer, in turn, is mounted using solder bumps on an IC package substrate such as a laminate substrate containing multiple ABF (Ajinomoto build-up film from Ajinomoto Fine-Techno Company of Japan)/Cu interconnect layers, and copper filled plated through holes (PTHs) with the laminate substrate assembled on a PCB. The performance of 3D ICs depends on the ability to move signals and power through these tiny wires in the ICs, interposer, IC substrate and PCB. This statement applies not just to 2.5D IC (see FIG. 1) but also other advanced SiPs (system-in-a-packages), notably, fan-out structure (see FIG. 2), embedded SiP (see FIG. 3), and silicon photonics (FIGS. 23A and 23B) as well as their combinations.

As transistors get smaller and smaller (as IC or silicon technology scaling continues), interconnects on ICs have to also scale in size and in the product of R and C (i.e., RC) where R is electrical resistance and C is capacitance. Fast chips need the RC value to be low since device speed is inversely proportional to RC. Scaling in or shrinking of interconnect dimensions, chiefly, the line width (L)/line spacing (S), the diameter and pitch of through vias and the bonding pad pitch, covering IC, interposer, IC substrate and 3D IC package, reduces the distance electrons must travel, the line resistance R and the power loss, thereby helping transistor speed to continue to increase while keeping other conditions the same. Migration from aluminum interconnects to the lower resistance copper interconnects in 1990s also helps reduce the R value (and improve reliability) for advanced ICs. Low-κ dielectrics (κ=2.5) used in the BEOL structure of advanced ICs today also reduces the C value compared with κ=4.2 for pure silicon dioxide as capacitance is a function of the dielectric's κ value. In comparison, the κ values for polyimides used in the RDL of interposer, ABF in IC laminate substrate and FR4/5 for PCB are, respectively, 2.78 to 3.48, 3.2 to 3.4 and 3.3 to 4.8, depending on glass fabric weave style.

For 3D ICs containing the most advanced disparate ICs located in close proximity, interconnect scaling needs to cover not just IC but also the interposer, IC package substrate, IC package and PCB in order to reap the full benefits of 3D ICs. Although 3D ICs enable significant benefits compared to 2D integration, there exist a noticeable divide or asymmetry between the dimensions of transistors and the dimensions of TSVs in active dies. Today, the channel length of modern transistors has already reached 10 nm or less, which is far smaller than the diameter of typical TSV of a few micrometers in active ICs. In addition, there exist divides in the L/S, the pitch of through vias and interconnect bonding pad pitch: (1) between wafer BEOL and interposer processes; (2) between interposer and IC substrate processes; and (3) between IC substrate and system-level PCB processes. As can be seen in FIG. 4, L/S and layer thickness decrease from PCB to IC substrate to advanced SiPs such as wafer-level fan-out packages to wafer BEOL covering a wide spectrum from 100 μm/100 μm to 0.2 μm/0.2 μm in L/S, and from 100 μm to 0.1 μm in layer thickness. Regarding TSV dimensions and interconnect bonding pad pitch as shown in FIG. 5, TSVs in active dies and interposers can be 1 μm to 40 μm in pitch while the usually thinner active dies tend to implement smaller pitches compared to thicker interposers. On HBM die stacks, SK Hynix recently announced its HBM3 DRAM which consists of 12 DRAM dies (each about 30 μm thick) with m-scale TSVs mounted on a control IC. In contrast, the plated through holes in build-up laminate substrates can be as small as 30 μm in diameter at a pitch of around 50 μm. Corresponding through hole dimensions for PCB often times are far larger than those for IC substrates and tend to vary widely by application.

Still referring to FIG. 5, flip chip assembly and the newly emerged copper hybrid bonding are two primary chip/interconnect bonding techniques in use today. Bond pad pitch or I/O scaling for 3D ICs (and other SiPs as warranted) is key to delivering increased bandwidth and lower power for high performance computing and in-memory computing applications. Mainstream ultrafine-pitch micro-bump solder based flip chip can achieve a bond pitch of 40 μm for chip-to-chip bonding, whereas the solder-less copper hybrid bonding technique for chip-to-chip bonding or bonding of silicon layers is capable of a bond pitch of 1 μm today and beyond down the road.

The above chip/package/system interconnection divides or asymmetries presents a significant limitation on the density and granularity that can be achieved by 3D IC integration, as well as PPAC optimization per “cubic millimeter” for 3D ICs.

### SUMMARY

It is one aspect of the present disclosure to provide a semiconductor package, including an integrated circuit (IC) block having a first interconnect layer and a first substrate carrying the IC block. The first substrate includes a second interconnect layer facing the first interconnect layer and a third interconnect layer opposite to the second interconnect layer. At least one of the second interconnect layer or the third interconnect layer is composed of a dielectric material and a conductive material substantially identical to a corresponding dielectric material and a corresponding conductive material of the first interconnect layer.

It is another aspect of the present disclosure to provide a semiconductor package, including a first substrate having a first interconnect layer and a second interconnect layer opposite to the first interconnect layer. The first interconnect layer is configured for hybrid bonding to an integrated circuit (IC) block or a second substrate with the first interconnect layer having a first dielectric and a first line width. The second interconnect layer has a second dielectric and a second line width. The first dielectric is identical to or different from the second dielectric, and the first line width is identical to or different from the second line width.

It is yet another aspect of the present disclosure to provide a semiconductor package, including a first substrate, having a pre-preg wiring layer, a first build-up wiring layer over a top surface of the pre-preg wiring layer, and a first repassivation wiring layer over a top surface of the first build-up wiring layer. The first build-up wiring layer has a minimal L/S between 6 μm/6 μm and 10 μm/10 μm. The first repassivation wiring layer has a minimal L/S equal to or smaller than 2 μm/2 μm. The first repassivation wiring layer is composed of a polyimide or an oxide, forming a first interconnect layer configured to bond to an integrated circuit (IC) block or another substrate.

### BRIEF DESCRIPTION OF THE DRAWINGS

Aspects of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 illustrates a cross-sectional view of a 2.5D/3D IC packaging structure according to some comparative embodiments of the present disclosure.

FIG. 2 illustrates a cross-sectional view of a fan-out structure according to some comparative embodiments of the present disclosure.

FIG. 3 illustrates a cross-sectional view of an embedded SiP structure according to some comparative embodiments of the present disclosure.

FIG. 4 illustrates schematic diagram of a landscape of advanced semiconductor packaging technology.

FIG. 5 illustrates a schematic diagram of a I/O scaling of semiconductor packaging technology.

FIG. 6 illustrates a schematic diagram of the evolution of substrate technology in response to state-of-the-art IC advancement.

FIG. 7 illustrates a cross-sectional view of an active IC according to some embodiments of the present disclosure.

FIG. 8 illustrates a cross-sectional view of an IC packaging substrate according to some embodiments of the present disclosure.

FIG. 9 illustrates a cross-sectional view of a passive component in a semiconductor package according to some embodiments of the present disclosure.

FIG. 10A illustrates a cross-sectional view of TSV according to some embodiments of the present disclosure.

FIG. 10B illustrates a cross-sectional view of a process of hybrid bonding according to some embodiments of the present disclosure.

FIG. 10C provides myriads of 3D IC package options, according to some embodiments of the present disclosure.

FIG. 10D provides manufacturing processes of a 2.5D silicon interposer, according to some embodiments of the present disclosure.

FIG. 11 illustrates a cross-sectional view of a 3D IC stacking process according to some embodiments of the present disclosure.

FIG. 12 illustrates a cross-sectional view of a 3D IC stacking process according to some embodiments of the present disclosure.

FIG. 13 illustrates a cross-sectional view of a 3D IC stacking process according to some embodiments of the present disclosure.

FIG. 14 illustrates a cross-sectional view of a 3D IC stack according to some embodiments of the present disclosure.

FIG. 15 illustrates a cross-sectional view of a 3D IC stack according to some embodiments of the present disclosure.

FIGS. 16A to 16F illustrates cross-sectional views of a 3D IC stacking process via fan-out processing according to some embodiments of the present disclosure.

FIG. 16G illustrates a cross-sectional view of a 3D IC stack using fan-out substrate according to some embodiments of the present disclosure.

FIG. 17A illustrates a cross-sectional view of a semiconductor package according to some embodiments of the present disclosure.

FIG. 17B illustrates a cross-sectional view of a semiconductor package according to some embodiments of the present disclosure.

FIG. 18 illustrates a cross-sectional view of a semiconductor package according to some embodiments of the present disclosure.

FIG. 19 illustrates a cross-sectional view of a semiconductor package according to some embodiments of the present disclosure.

FIG. 20 illustrates a cross-sectional view of a semiconductor package according to some embodiments of the present disclosure.

FIG. 21 illustrates a cross-sectional view of a semiconductor package according to some embodiments of the present disclosure.

FIG. 22 illustrates a cross-sectional view of a semiconductor package according to some embodiments of the present disclosure.

FIG. 23A illustrates a cross-sectional view of a SiP co-package according to some embodiments of the present disclosure.

FIG. 23B illustrates a cross-sectional view of a processor-photonic SiP co-package according to some embodiments of the present disclosure.

FIG. 24 illustrates a cross-sectional view of a laminate substrate with single-sided RDL according to some embodiments of the present disclosure.

FIG. 25 illustrates a cross-sectional view of a laminate substrate with double-sided RDL according to some embodiments of the present disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer, or section from another. The terms such as “first”, “second”, and “third” when used herein do not imply a sequence or order unless clearly indicated by the context.

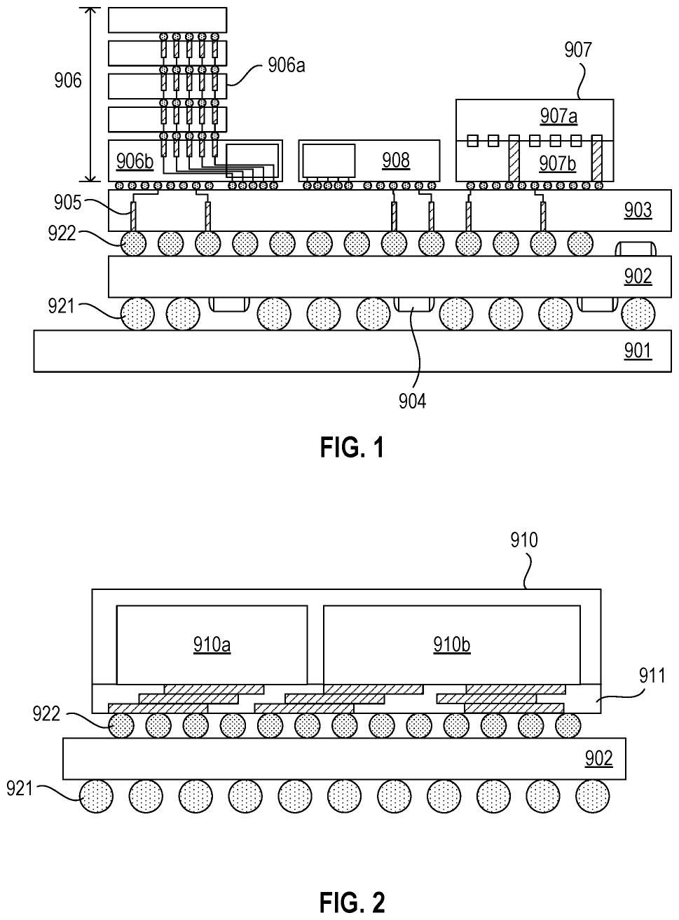

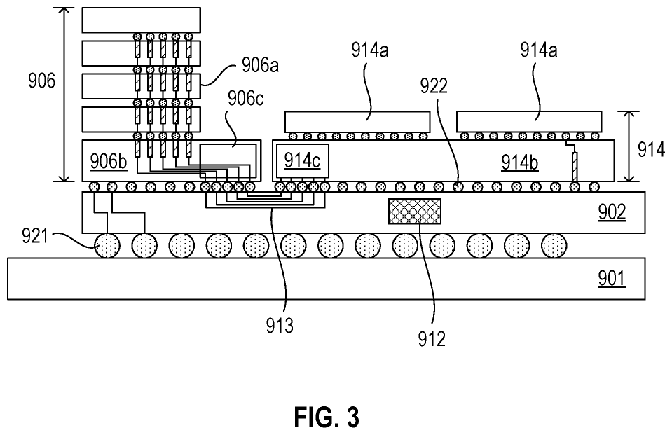

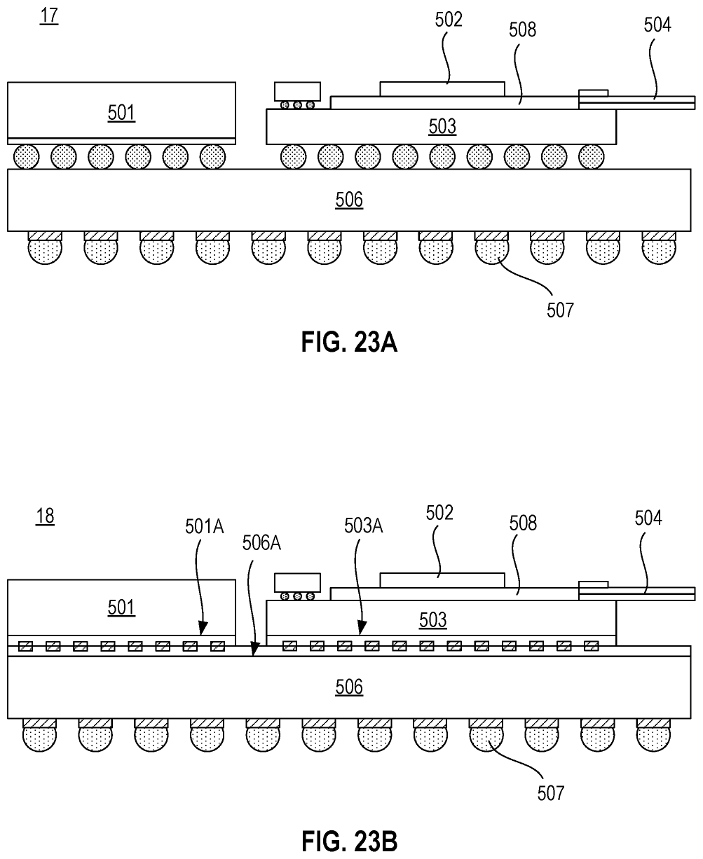

The present disclosure discloses methodologies, processes and structures to speed up interconnect scaling for 3D ICs (and other advanced System in a Packages (SiPs) as warranted) way ahead of traditional interconnect scaling curves of related IC, interposer, IC substrate, IC packaging and test, and printed circuit board (PCB) industries, while in the process bridging the aforementioned chip/package/system divides in the aforementioned critical interconnect dimensions. Another intent of the present disclosure is to disclose methodologies to allow for “continuously” bridging these divides and “continuing” scaling of interconnect dimensions as they evolve, leading to “continuing” creation of novel, densest 3D ICs and 3D IC packages. Although examples are provided herein based on 3D ICs and 3D IC packages, the present disclosure can also be applied to other types of advanced ICs and advanced SiPs comprising primarily 2.5D/3D IC (see the example in FIG. 1), fan-out (see the example in FIG. 2), embedded SiP (see the example in FIG. 3), silicon photonics (see the examples in FIGS. 23A and 23B) and their combinations.

As in the 2.5D IC structure depicted in FIG. 1, in some comparative embodiments, a PCB 901 is utilized as a carrier, while a laminate substrate 902 is bonded over the PCB 901 through a plurality of ball grid array (BGA) balls 921. The laminate substrate 902 may have one or more passive components 904 mounted on one or both sides of the laminate substrate 902 and/or embedded in the laminate substrate 902. A silicon interposer 903 is bonded over the laminate substrate 902 through a plurality of solder bumps 922. The silicon interposer 903 with through silicon vias (TSVs) 905 can be used as a platform to bridge fine L/S/pitch capability gap between the laminate substrate 902 and the ICs, 906, 907 and 908. Over the silicon interposer 903, different electronic components such as dynamic random-access memory (DRAM) structure 906, logic structure 907, or central computing unit 908, etc., can be mounted on the upper side of the silicon interposer 903 where the ICs in the electronic components can be stacked in 3D as shown by 906 and 907 in FIG. 1. For instance, the DRAM structure 906 in FIG. 1 can be a HBM DRAM stack which includes a plurality of vertically (in the thickness direction) mounted DRAM dies 906a (using flip chip bonding based on micro-bumps or hybrid bonding) that is vertically stacked on a base die, i.e., a control IC 906b (again using micro-bumps), while these micro-bumps are coupled with TSVs in the DRAM dies 906a. In another example, the logic structure 907 may include a memory die 907a vertically stacked on a logic die 907b, while the memory die 907a is bonded to the logic die 907b through hybrid bonding layers (or flip chip bonding), and some of the hybrid bonding bond pads may be coupled with the TSVs in the logic die 907b.

Referring to FIG. 2, in some comparative embodiments, a fan-out package structure can be adopted with connections fanned out from the chip surface to enable more external I/Os. As shown in FIG. 2, the semiconductor chip 910 can include one or more semiconductor dies (e.g., die 910a and die 910b) which are connected to a fan-out structure 911 (e.g., RDL) that can consist of a layer for subsequent hybrid bonding or be coupled with solder bumps 922 (or micro-bumps). Using flip chip bonding or copper hybrid bonding, the fan-out structure 911 is bonded to the laminate substrate 902.

Referring to FIG. 3, in some comparative embodiments, an embedded SiP may include a passive device 912 and a silicon interconnect 913 embedded in the laminate substrate 902. The silicon interconnect 913 establishes electrical connections between the physical layers (PHY) 906c of the DRAM structure 906 and the PHY 914c of a device structure 914. The device structure 914 may include a processor die, a memory die, a radio frequency (RF) die, a field programmable gate array (FPGA) die, etc. 914a, bonded on a base logic die 914b containing TSVs. The DRAM structure 906 and the device structure 914 are bonded to the laminate substrate 902 through solder bumps 922.

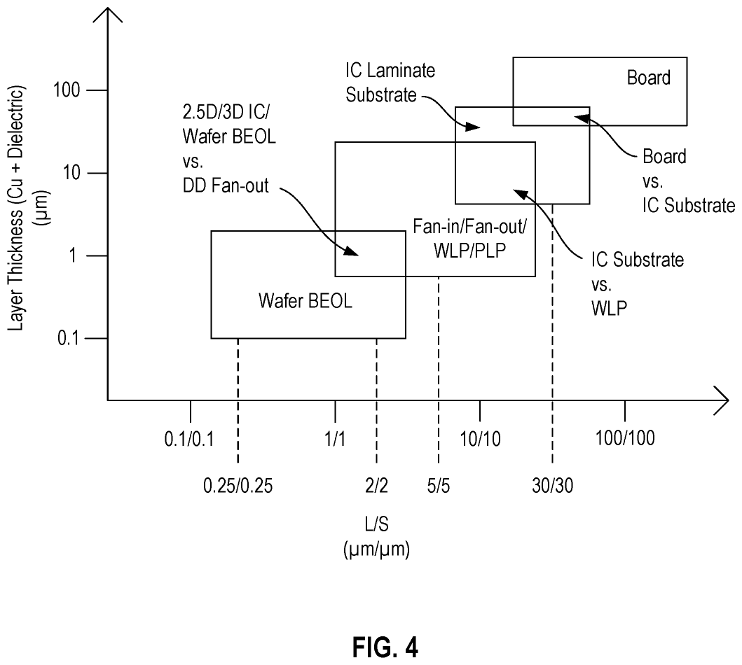

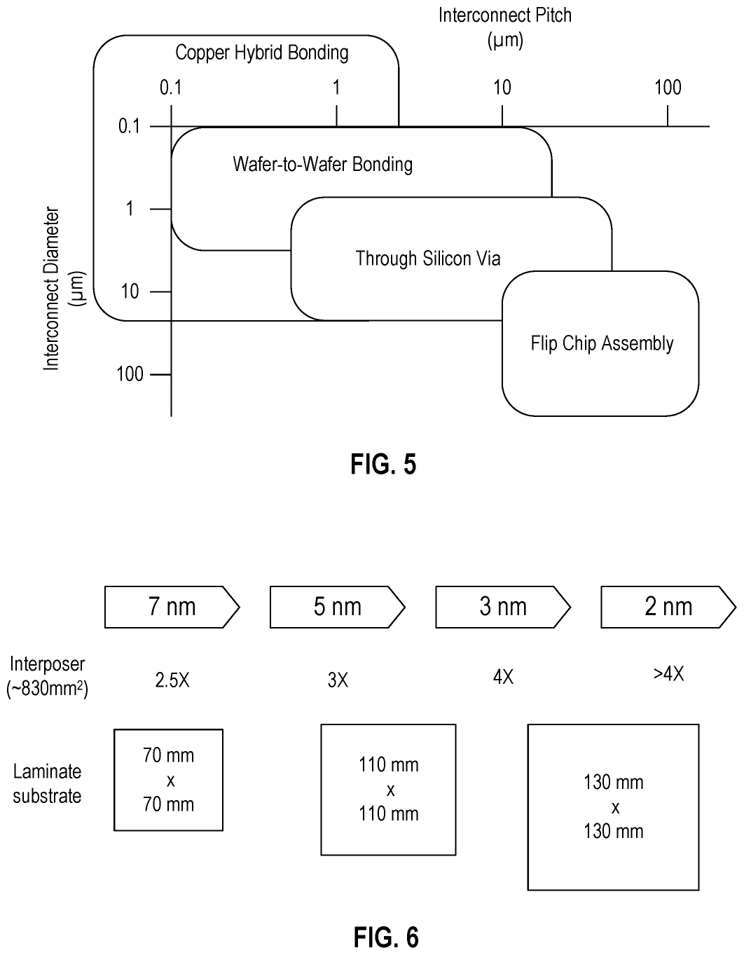

Regardless of the advanced SiP styles, the mainstream, best-can-do line width (L)/line spacing (S) deployed in advanced SiPs today is typically around 0.2 μm/0.2 μm, 2 μm/2 μm, and 6 μm/6 μm, respectively, for wafer BEOL, 2.5D/3D/fan-out and ABF based laminate substrate with corresponding interconnect layer thickness at 1 μm, 5 μm, and 20 am. As can be seen in FIG. 4, the corresponding dimensions for PCB are typically far larger than those for the IC substrate and they often vary widely even for the same end application. TSVs in active dies (as shown in FIG. 5) can be 2 μm to 6 μm in diameter, 4 μm to 15 μm in pitch and 25 μm to 30 μm in depth (or sometimes called length), whereas TSV dimensions in 2.5D silicon interposers are typically 5 μm to 20 μm in diameter, 10 μm to 40 μm in pitch and 25 μm to 100 μm in depth (i.e., silicon interposer thickness). TSV dimensions for active dies are typically much smaller than those for the larger interposers although the base technology is the same for both applications. In contrast, plated through holes in build-up laminate substrates can be as small as 30 μm in diameter with a pitch of 60 μm and can have a depth of 400 μm (assuming a two-layer core) or larger.

There also exists a gap in bond pitch (and bond pad diameter) between flip chip bonding and copper hybrid bonding (as shown in FIG. 5). Solder based micro-bump today is at a mainstream finest pitch of about 40 μm (some said about 36 μm) and solder-less copper hybrid bonding at 6 μm to mainstream in contrast to about 400 μm for solder bonding the interposer to the laminate substrate and far greater than 400 μm for solder bonding the laminate substrate to the PCB.

As the advanced silicon technology is scaling from 5 nm to 2 nm in support of high performance computing (HPC), data center and other high-performance applications such as artificial intelligence (AI), larger and higher-layer count organic laminate substrates is required for advanced processor ICs such as CPU, GPU and FPGA even with the incorporation of 2.5D silicon interposers that take away some of the interconnect duties from the laminate substrates (as shown in FIG. 6). In the next few years as the industry scales to 2 nm, a gigantic 130 mm×130 mm laminate substrate containing an astounding 10+6+10 layers (6-layer core and 10 layers of build-up on both sides of the core, making a total of 26 layers) will be required in support of the silicon technology beyond 3 nm. This next-generation substrate contains 30% more layers compared to that required by the 5 nm silicon technology and has an area that is 1.4× that required by the 5 nm technology, as shown in FIG. 6. Given the aforementioned best-can-do mainstream L/S build-up substrate capabilities, larger-than-ever laminate substrate sizes and higher-than-ever layer counts will inevitably give rise to lower substrate yields and higher substrate costs in laminate substrate processing which relies on large panels (e.g., 20″×24″) based on ABF resin and BT resin (bismaleimide triazine resin, which was developed by Mitsubishi Gas Company of Japan).

Even though the substrate industry and related equipment industries have been endeavoring to scale to ultrafine lines and spaces in panel-level substrate processing in order to reduce the substrate sizes and layer counts, it is still years away for mainstream, high volume, high-yield panel-level build-up substrate processes to scale to 2 μm/2 μm L/S and beyond (i.e., the interposer capability today) with high yields, particularly for applications requiring the aforementioned unprecedented large substrate sizes and high layer counts. As advanced ICs scale, not only does the laminate substrate get bigger the interposer also needs to get bigger, as shown in FIG. 6. Similar statements can be made on interposer and PCB interconnect scaling: higher integration at laminate requires higher integration at the interposer and the PCB.

When it comes to advanced SiPs with 3D IC packaging in particular, there exist three main divides in critical dimensions: between IC/wafer BEOL and interposer, between interposer and laminate, and between laminate and PCB. All the divides need to be bridged in order to maximize the benefits of 3D ICs. Speeding up interconnect scaling has many benefits. Higher levels of integration through faster interconnect scaling can lead to smaller interposer and substrates sizes and fewer interconnect layers, as well as lower costs. This will not only address the challenges imposed on advanced interposers and IC laminate substrates by advanced ICs but will also enable 3D ICs and 3D IC packaging to pack in higher function densities for higher performance and lower power consumption, while keeping other conditions the same.

For the IC, IC packaging, laminate substrate and PCB industries and as disclosed herein, expediting interconnect dimension scaling by using or borrowing mainstream finer L/S/pitch technologies from other or adjacent industries stands to bridge the aforementioned chip/package/system interconnect divides faster compared to adhering to the normal technology advancement curves within the respective industries. More importantly, it allows one to churn out more densely packed 3D ICs and advanced SiPs (such as those shown in FIGS. 1, 2, 3, 23A and 23B and their combinations) ahead of normal industry technology advancement curves. As the L/S/pitch technologies of the IC, IC package, laminate substrate and PCB industries continue to scale and refine, the methodologies, structures and processes disclosed herein can continuously be implemented (by, for example, continuously leveraging the best-can-do mainstream finer L/S/pitch technologies from adjacent industries) to allow one to create SiPs with the highest function integration densities possible at any given time.

In the present disclosure, the main divides in interconnect scaling capabilities covering 3D IC stacking, and interconnections involving 3D IC-to-interposer, interposer-to-laminate and laminate-to-PCB are bridged in a holistic and generalized manner by applying:
(1) for denser 3D IC stacking: finer-pitch wafer BEOL oxide-to-oxide (or other suitable material combinations) copper hybrid bonding and via-last integration to replace traditional flip chip bonding based on micro-bumps;
(2) for denser 3D IC to interposer interconnection: finer-pitch wafer BEOL SiO₂/Cu RDL to replace traditional PI/Cu RDL in the interposer on the IC side of the interposer, finer-scale TSVs for ICs to replace coarser dimension TSVs for interposers, and finer-pitch wafer BEOL oxide-to-oxide hybrid bonding of the 3D IC to the interposer to replace flip chip bonding;
(3) for denser interposer to laminate interconnection: finer-pitch PI/Cu RDL (or finer-pitch low-deposition-temperature (LDT) oxide/Cu RDL) to replace traditional ABF/Cu RDL in the laminate substrate on the interposer side, and finer-pitch PI-to-PI (or oxide-to-oxide) hybrid bonding to replace solder based flip chip bonding of the interposer to the laminate substrate, and/or
(4) for denser laminate to PCB interconnection: similar to the above for interposer-to-laminate.

When needed, one can also
(1) apply finer-pitch wafer BEOL SiO₂/Cu RDL to replace the traditional PI/Cu RDL for the RDLs on the top side and bottom side of the interposer for bonding through flip chip and/or hybrid bonding.
(2) apply finer-pitch PI/Cu RDL (or finer-pitch LDT oxide/Cu RDL) to replace the traditional ABF/Cu RDL for the RDLs on the top side and bottom side of the laminate substrate for bonding through flip chip and/or hybrid bonding.

With minimal process tuning, the methodologies, processes and structures disclosed herein allow for interconnect scaling way ahead of traditional scaling in industries pertaining to IC, interposer, laminate and PCB, taking advantage of capacities that already exist in adjacent industries.

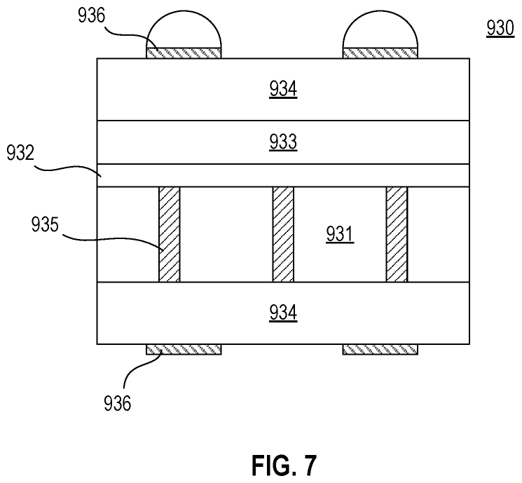

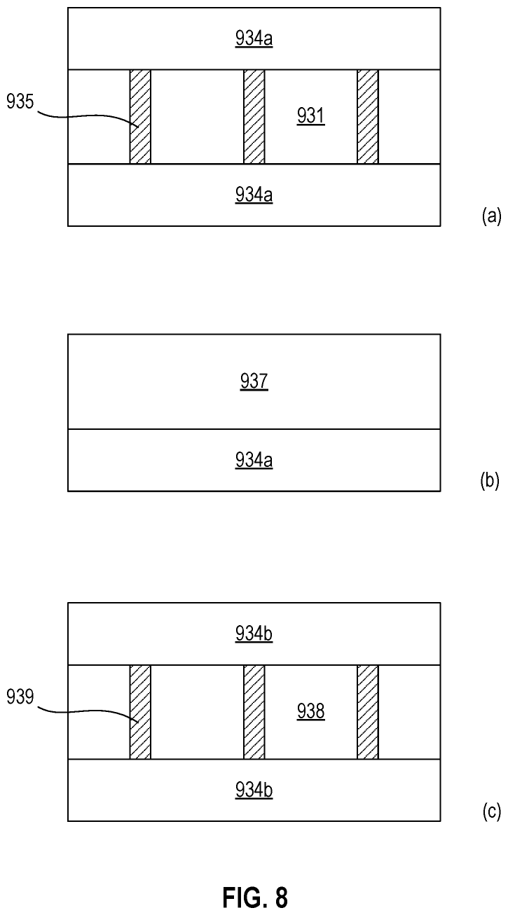

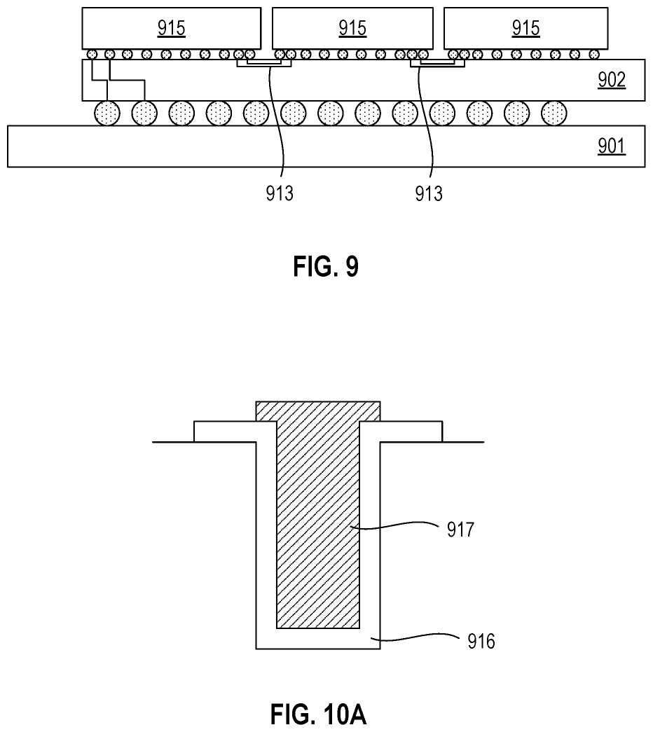

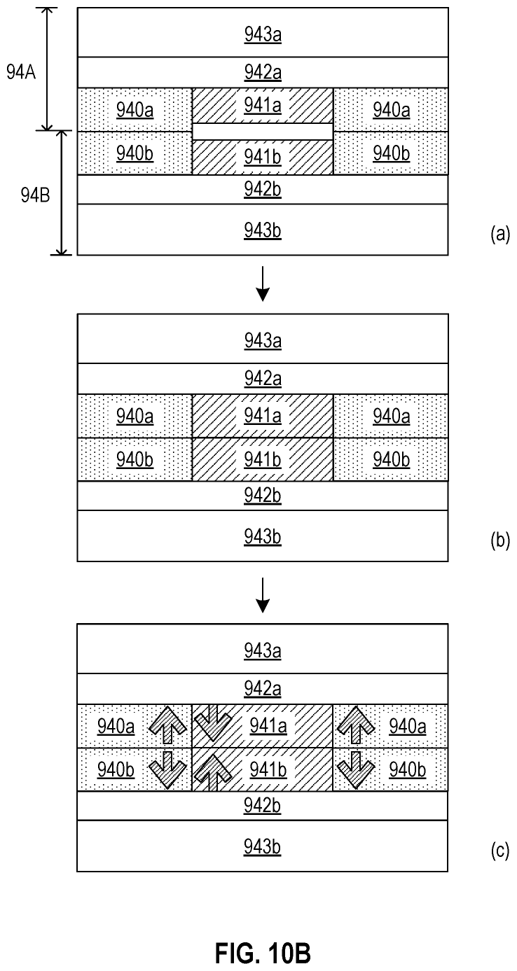

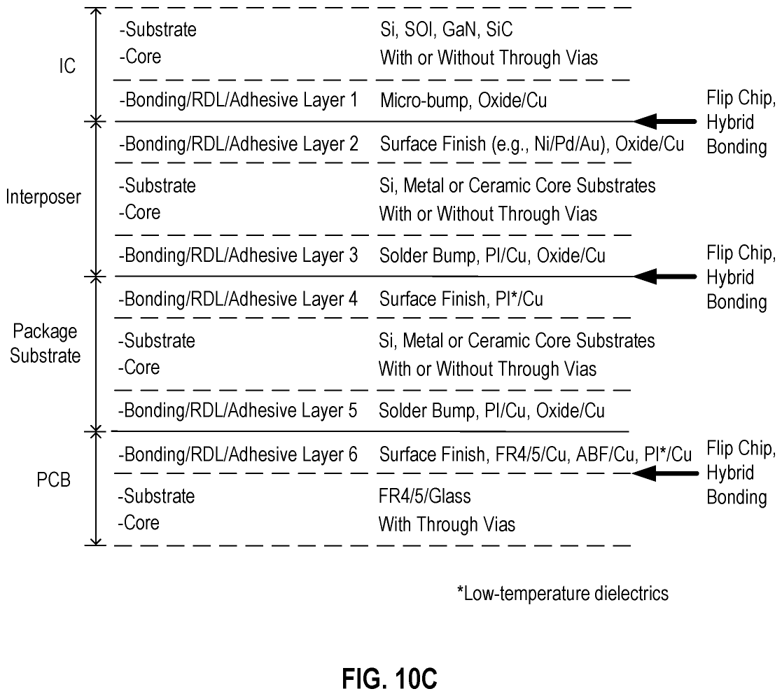

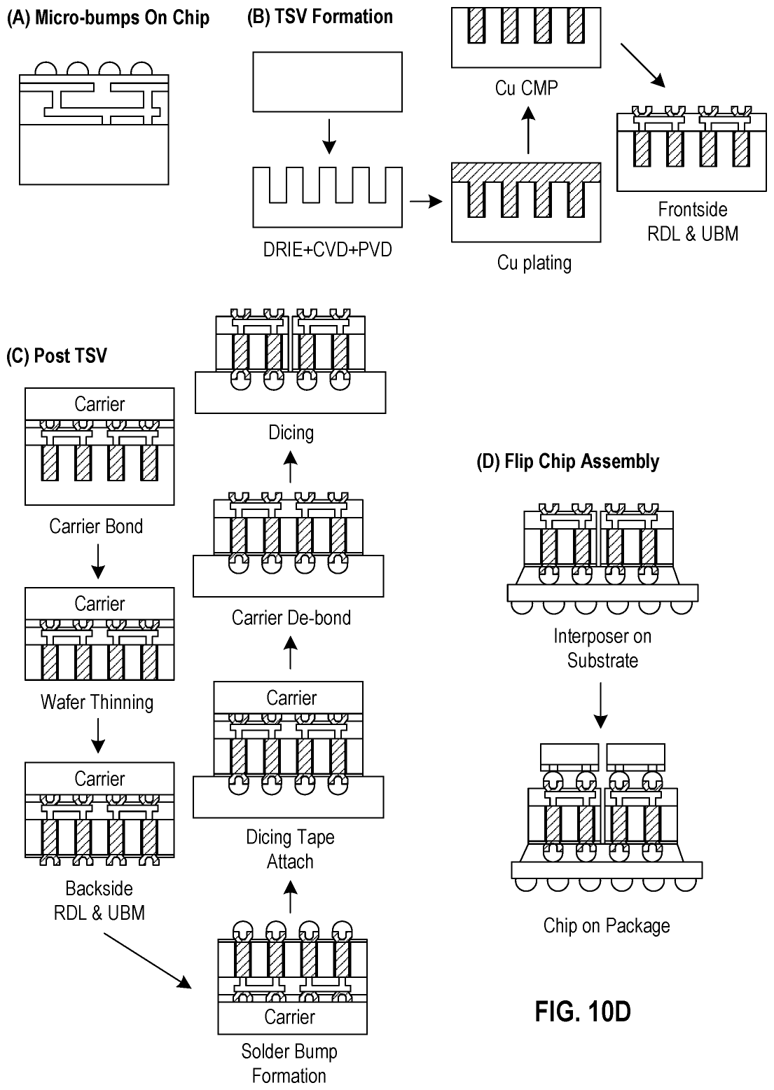

The previously shown comparative embodiments related to FIGS. 1, 2, 3, 23A and 23B as well as other SiP-related figures disclosed herein illustrate specific applications of advanced SiPs. Furthermore, FIGS. 7 to 10 depict examples of the state-of-the-art building block technologies that enable these advanced SiPs. These technologies include the enabling active IC in FIG. 7, the enabling IC package substrates (including interposers) in FIG. 8, examples of enabling passives in FIG. 9, and TSV options in FIG. 10A.

Referring to FIG. 7, a state-of-the-art IC similar to that appearing in the HBM DRAM stack is shown with TSVs, RDL one side or on both the top side and the bottom side of the die, bonding pads on both sides, at least one of which contains solder/micro-solder bumps. The semiconductor structure 930 in FIG. 7 includes a silicon substrate 931 having a plurality of TSVs 935. A front-end-of-line (FEOL) structure 932 is located over a front side of the silicon substrate 931, a back-end-of-line (BEOL) structure 933 is located over the FEOL structure 932, and RDL 934 can be disposed on a back side of the silicon substrate 931 and also on the BEOL structure 933. In some embodiments, the BEOL structure includes the combination of low-k material and copper, the combination of SiO₂ and copper, or the like. In some embodiments, an on-chip passive component can be formed in the BEOL structure 933. In some embodiments, the RDL 934 contains a plurality of bonding pads for external connections. Alternatively, in other embodiments, the surface of RDL 934 may be furnished with or without the bonding pads 936, micro-bumps, or solder bumps.

On the top side, the RDL 934 can, in fact, be one with the BEOL structure 933 underneath it. In some embodiments, the RDL 934 includes combinations of dielectric material and copper, or the combination of polyimide and copper. In some embodiments, the RDL 934 may be formed with surface finish and passivation layers as needed. In some embodiments, the RDL 934 and/or the semiconductor structure 930 can have passive components (and/or optical components) formed inside or mounted on. Moreover, in some embodiments, the RDL 934 can contain the dielectric/Cu structure required for hybrid bonding.

FIG. 8 shows the three types of enabling IC package substrate: (a) the silicon substrate 931 (e.g., the interposer) with PI/Cu RDL 934a and TSVs 935; (b) the fan-out structure that consists of wafer-level (or analogously panel-level in the present disclosure) PI/Cu RDL 934a and molding compound 937; and (c) the IC laminate substrate with RDL 934b consisting typically of ABF/Cu or BT/Cu based build-up layers and a core 938 consisting typically of BT/glass or FR4/FR5/glass. A plurality of plated through holes (PTH) 939 are formed in the core 938, establishing electrical connections between the two RDL 934bs. In some embodiments, the three substrate structures shown in FIG. 8 can have passive components (and/or optical components) formed inside or mounted thereon.

In some embodiments, the on-chip passive devices created in-situ by IC processes, as well as discrete passive devices, can be integrated with the BEOL/RDL structures. As shown in FIG. 9 in high performance computing (HPC) applications, the inclusion of passive components such as the silicon interconnects 913 (which can be passive or active), embedded within the laminate substrate 902 to interconnect different dies 915, is often advisable. In other embodiments, passive components such as IC capacitors (e.g., deep trench capacitors, and low-inductance chip arrays capacitors) can be manufactured using processes like those employed in IC production.

FIG. 10A illustrates a generic TSV structure. As depicted in FIG. 10A, TSVs can be created using different combinations of adhesion-barrier/seed layer and conductor. In some embodiments, candidate materials of the conductor 917 in the TDV include copper, tungsten, cobalt and ruthenium, while candidates of the adhesion-barrier layer 916 includes Ti, TiN/Ti, Ta, TaN/Ta, TaN/Co, or the like. When copper is used as the seed layer for copper plating, the conductor material should be copper.

The present disclosure proposes hybrid bonding, as illustrated in FIG. 10B, which provides several advantages over flip chip technology in terms of finer pitch, RC delay, IC drop, thermal characteristics, bandwidth, I/O energy, and area overhead. However, it should be noted that flip chip technology holds an advantage over hybrid bonding in terms of maturity, relaxed planarization requirements, and test and yield management.

FIG. 10B illustrates a copper hybrid bonding process flow. Hybrid bonding which enables the achievement of ultrahigh function integration densities relies on the utilization of a bonding layer, typically SiO₂, deposited on two opposing wafer surfaces. Alternative dielectric materials like Si₃N₄ can also be considered.

The copper hybrid bonding approach allows for aligned wafer-to-wafer bonding at relatively low temperatures, usually below 400° C. By limiting the thermal exposure to temperatures to below 400° C. (preferably below 250° C.), conventional metallization and low-x dielectrics such as copper and carbon-containing low-x BEOL can be utilized. Generally, the advantages of low-temperature bonding including the avoidance of excessive wafer deformation due to thermal expansion match effects, and minimizing the thermal effects on the lower layer transistor high-x metal gate stacks and functions.

The dielectric layer for hybrid bonding can be created on the top of typical wafer BEOL interconnection layers. This is followed by chemical-mechanical polishing (CMP) of the wafer surfaces to substantially planarize wafer surfaces and expose metal pads, as well as surface cleaning, plasma surface activation and water pre-wetting of the dielectric surfaces, preparing them for wafer-to-wafer bonding. Referring to operations (a) to (c) in FIG. 10B, a wafer 94A is bonded to a wafer 94B, where the wafer 94A, for example, includes a silicon substrate 943a in contact with the BEOL structure 942a. On a surface of the BEOL structure 942a, the thickness of the RDL/bonding layer 940a is slightly greater than that of a conductive metal pad 941a. In some embodiments, the structure of wafer 94A is mirroring substantially the structure of wafer 94B, and the features regarding the RDL/bonding layer 940b, and the conductive metal pad 941b are substantially identical to those in wafer 94A.

Referring to operations (a) to (c) in FIG. 10B again, the three-step wafer-to-wafer process can include: (a) oxide-to-oxide bonding (i.e., silicon dioxide-to-silicon dioxide bonding) at low/room temperature; (b) heating to close the gap between conductive metal pads (taking advantage of the higher coefficient of thermal expansion, CTE, of metal versus the CTE of oxide); and (c) further heating to compress and bond the conductive metal pads with or without external pressures. Overall, operations (a) to (c) form the chemical bonds at the wafer dielectric interface and achieve metal bonding when metal pads are present. Direct oxide-to-oxide bonding proceeds generally in the following process sequence: (1) formation of dangling bonds and bonding between hydroxyl groups and water molecules through plasma activation using gases such as O₂ (oxygen)/N₂ (nitrogen)/Ar (argon); (2) removal of defects through deionized water cleaning and scrubbing; (3) bonding of wafers (or wafer and wafer-sized interposer) with similar oxide bonding layers at room temperature and atmospheric pressure via van der Waals hydrogen bonds between two to three monolayers of water molecules and polar hydroxyl (OH) groups (which terminate at both the native and thermal SiO₂); (4) formation of van der Waals bonds between H₂O molecules and silanol groups (Si—OH—(H₂O)x-HO—Si; silanol group ═Si—OH) on wafer surfaces; and (5) annealing to remove water molecules at the interface and form covalent bonds at temperatures typically less than 400° C. (and preferably below 250° C.) to prevent melting of the inter-metal layers and diffusion of implanted dopant. Void formation caused by water droplet formation (the Joule-Thomason expansion effect) at wafer edge during direct bonding must be avoided by controlling key parameters such as plasma conditions, surface roughness, degree of cleanliness, wafer warpage/flatness and bonding conditions. In the case of oxide-to-oxide bonding, one can also vary oxide type and deposition technique, process conditions such as plasma gas, plasma power, surface roughness pertaining to chemical mechanical polish (CMP), surface cleanliness, mono- to multiple layers of water molecules from de-ionized cleaning, bonding conditions (such as temperature and speed), and anneal conditions (e.g., anneal temperatures, anneal time and number of annealing steps) to maximize the bonding yield and shear strength between two wafers.

FIG. 10C exemplifies a wide range of material/process options for 3D IC packaging on PCB based on the methodologies, processes and structures disclosed herein. Other options also exist beyond what FIG. 10C indicates. The embodiments described herein includes configurations of one or more IC blocks, one or more interposers, one or more laminate substrates or package substrates, and one or more PCBs. Each of the IC blocks, interposers, laminate substrates or package substrates, or PCBs possesses respective interconnect layers configured to form electrical connection to one another. Material and structural options of the components and interconnect layer described herein can at least be selected from the description associated with FIG. 10C.

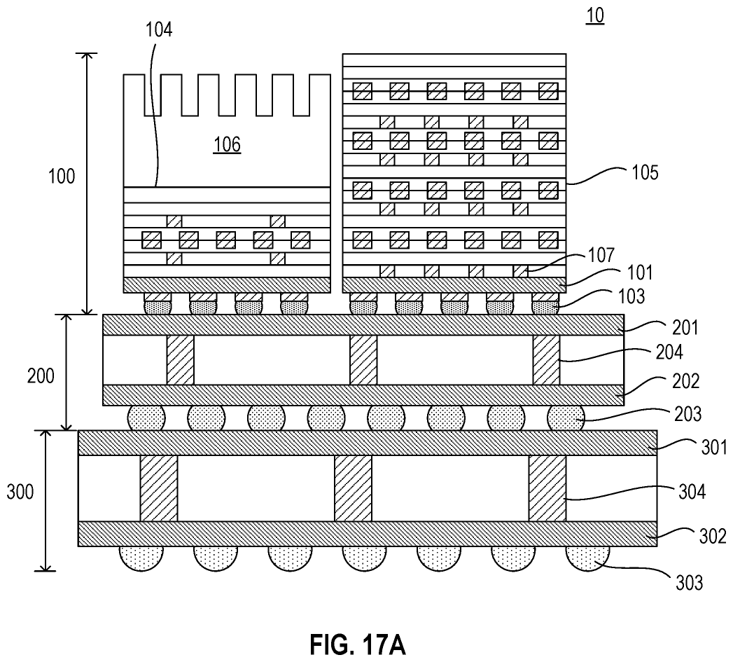

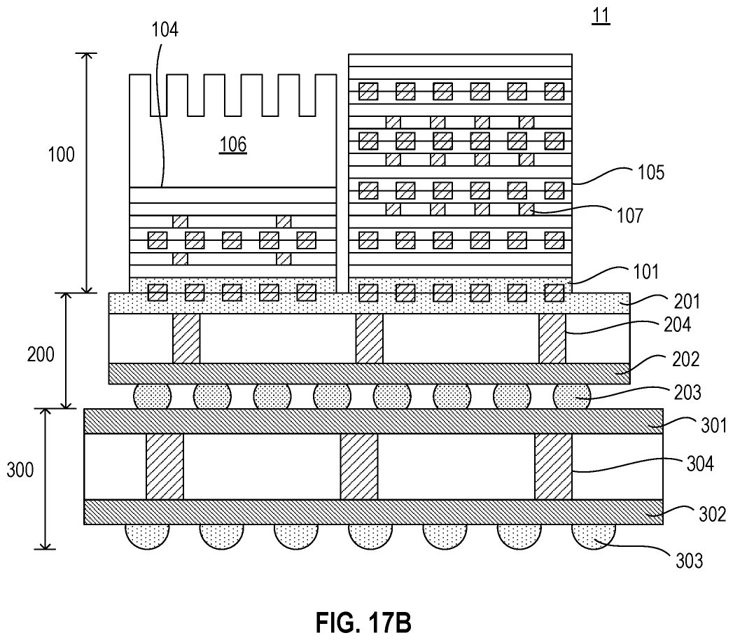

FIG. 10D provides manufacturing processes of a 2.5D silicon interposer. The mainstream processes used to create TSVs in silicon interposers with RDLs on both sides can be applied to fabricate interposers with oxide/Cu RDL on one side or both sides in support of the 3D IC packaging processes shown in FIG. 17A to FIG. 22. The TSV openings can be created by deep reactive ion etching (DRIE) of silicon using fluorinated gases such as CF₄, SF₆ or xenon difluoride (i.e., the Bosch etch process) as the etch gas. To create high-aspect ratio TSVs, masks of choice can include aluminum/silicon dioxide, aluminum/silicon/aluminum, stainless steel, aluminum, titanium, gold, chromium, silicon dioxide, aluminum oxide, photoresist and/or spin-on-glass. The etch mask material needs to be etched slower than silicon in DRIE with high selectivity. Ultra-short-pulse (e.g., femtosecond-pulsed) laser micromachining can also be used depending on the mask and DRIE conditions for improved etch performance. A combination of DRIE and epitaxial deposition can create ultra-high-aspect-ratio (up to 500) trenches in silicon. Following TSV hole opening, one can proceed to follow the 2.5D silicon interposer process flow shown in FIG. 10D (under operation (B) TSV formation) starting from plasma enhanced chemical vapor deposition (PECVD) of oxide, and physical vapor deposition (PVD) of barrier/seed titanium/copper (Ti/Cu) or tantalum nitride/Cu (TaN/Cu) liner by sputtering to copper plating to fill the TSVs to CMP to remove the overburden Cu and then to front-side (chip-side) m-level fine-line RDL and under-bump metallurgy (UBM) processing. This is followed by operation (C) post-TSV processes from carrier bond to wafer thinning to backside RDL and UBM to solder ball deposition to die tape attach to carrier de-bond to dicing to singulate the interposer. Operation (A) regarding micro-bumps on chip refers to creating micro-bumps on ICs or 3D ICs which will be bonded to the interposer after interposer assembly on the laminate substrate (under operation (D) Flip Chip Assembly). Because the interposer is very thin, a carrier (typically a glass substrate; see operation (C)) is bonded to the interposer substrate through an adhesive/release layer which can withstand the high temperatures incurred during the formation of the typically polyimide based redistribution layers (RDL) and which can be removed subsequently by shining a laser at it. Though variants exist, the flows under operations (C) and (D) in FIG. 10D show a flow to build the interposer post-TSV, assemble it on the laminate substrate and subsequently flip chip assemble the chips on the interposer to form the 2.5D IC previously described in FIG. 1.

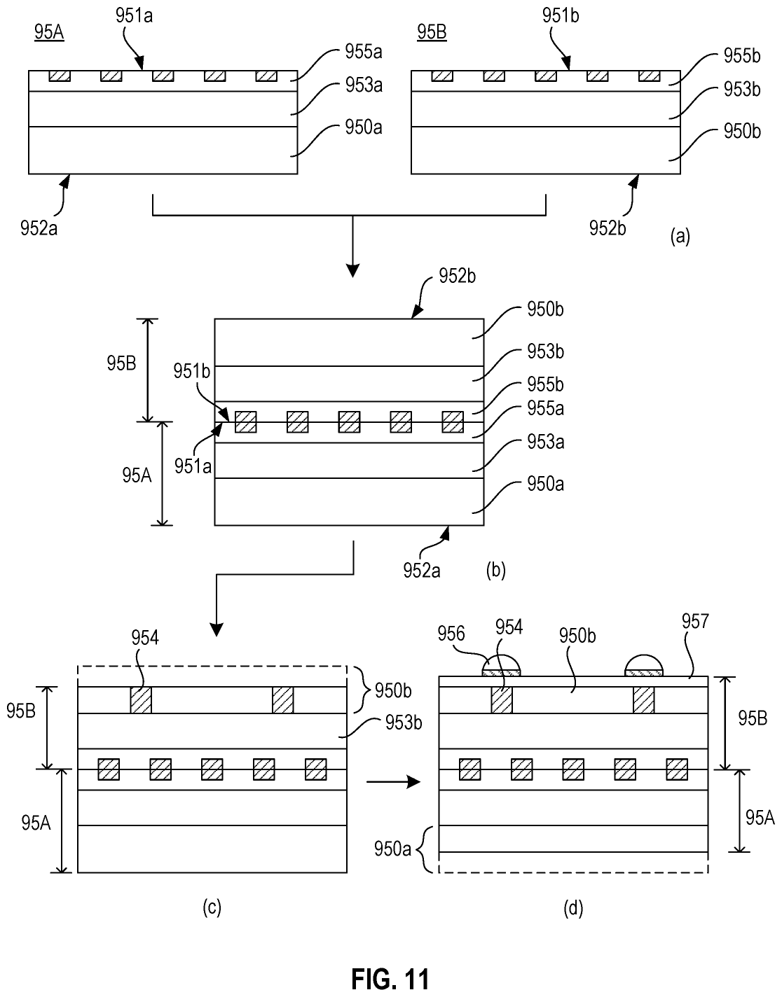

FIGS. 11 to 13 demonstrate examples of 3D IC stacking processes using hybrid bonding and via-last integration. The dies involved in the stacking can be memory dies, logic dies or memory and logic dies, and can be based on various IC technologies such as Si (silicon), GaN (gallium nitride), SOI (silicon on insulator), SiC (silicon carbide), and others.

As shown in operations (a) to (d) of FIG. 11, a face-to-face (F2F) two-die bonding process is depicted, which utilizes hybrid bonding between two opposing oxide/Cu layers with Cu metal pads of a first wafer 95A and Cu metal pads of a second wafer 95B.

In some embodiments, the first wafer 95A and the second wafer 95B comprise two silicon substrates, 950a and 950b, and two BEOL structures, 953a and 953b. The front sides, 951a and 951b, are on top of the BEOL structures, 953a and 953b, of the respective wafers 95A and 95B, and the back sides, 952a and 952b are on the opposite sides of 951a and 951b. In some embodiments, after the first wafer 95A is face-to-face (F2F) bonded to the second wafer 95B through the hybrid bonding layers, 955a and 955b (see operation (b)), one of the two silicon substrates, for example, the silicon substrate 950b, can be thinned as shown in operation (c). At least one or more TSVs 954 are formed in the silicon substrate 950b which connect the BEOL structure 953b to the RDL on the other side of the silicon substrate 950a. Structures of the hybrid bonding layers, 955a and 955b, can be referred to the previous description associated with FIG. 10B and are not repeated here for brevity. The hybrid bonding layers 955a and 955b can be either PI/Cu or oxide/Cu RDL. When PI/Cu is used, it is advantageous to apply an external pressure during hybrid bonding. As shown in operation (d) of FIG. 11, RDL 957 is then formed over the silicon substrate 950b, followed by formation of surface finish/under bump metallurgy (not shown) and solder/micro-solder bumps. In the embodiment described in FIG. 11, the TSVs 954 are created in the silicon substrate 950b using via-last processes after wafer-to-wafer bonding.

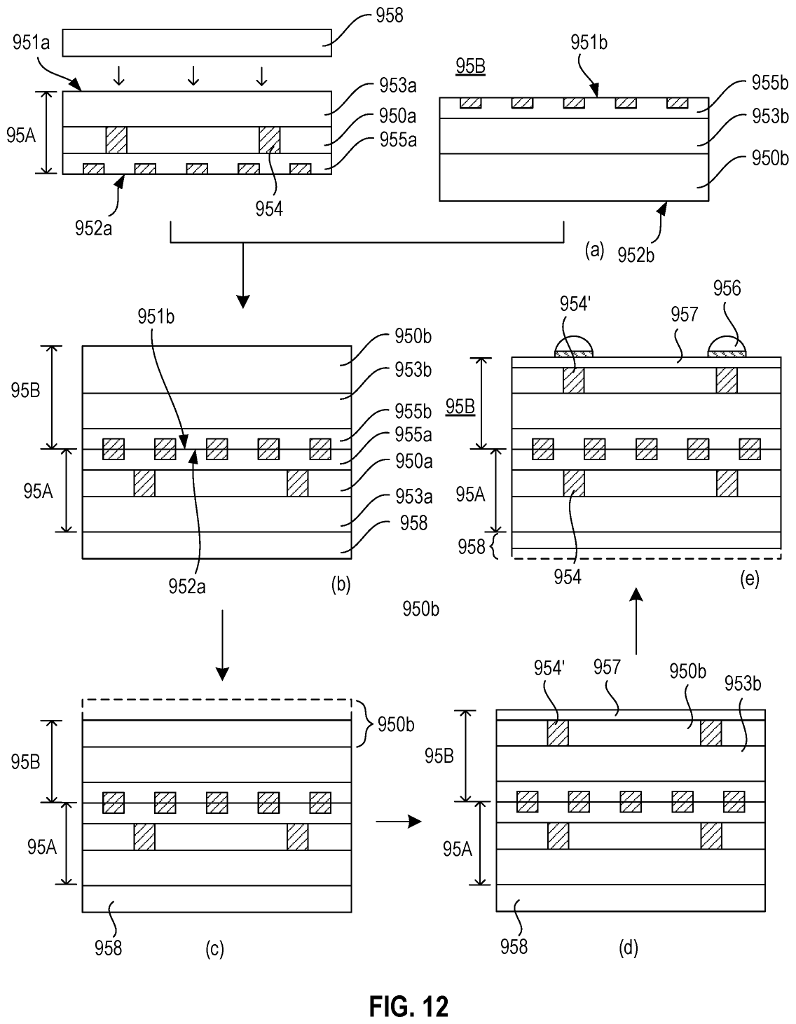

FIG. 12 illustrates the back-to-face (B2F) bonding processes using two dies as an example. As shown in operation (a) in FIG. 12, a base substrate 958 is attached to the BEOL structure 953a of the first wafer 95A. TSVs 954 in the silicon substrate 950a are formed through via-first or via-middle processes, i.e., prior to the wafer-to-wafer bonding operation. The hybrid bonding layer 955a is disposed over the silicon substrate 950a, and a surface of the hybrid bonding layer 955a coincides with the front side 952a of the first wafer 95A. Detailed description of the second wafer 95B in FIG. 12 can be referred to the counterpart 952a in FIG. 11 with identical numerals designating identical or equivalent components. In operation (b), the back side, 952a, of the first wafer 95A is hybrid bonded to the front side 951b of the second wafer 95B in a back-to-face (B2F) manner. Structures of the hybrid bonding layers, 955a and 955b, can be referred to the previous descriptions associated with FIG. 10B and are not repeated here for brevity. The hybrid bonding layers, 955a and 955b, can be both based on either PI/Cu or oxide/Cu RDL. When PI/Cu is used, an external pressure can be applied during hybrid bonding. In operations (d) and (e), one of the silicon substrates, for example, the silicon substrate, 950b, can be thinned and at least one or more TSVs 954′ are formed in the silicon substrate 950b connecting the BEOL structure, 953b, and the RDL on the opposite side of the silicon substrate. RDL 957 is then formed over the silicon substrate 950b, followed by formation of surface finish/under bump metallurgy (not shown) and solder/micro-solder bumps on RDL 957. In the embodiment described in FIG. 12, the TSVs 954′ are created in the silicon substrate 950b using via-last approach following wafer-to-wafer bonding.

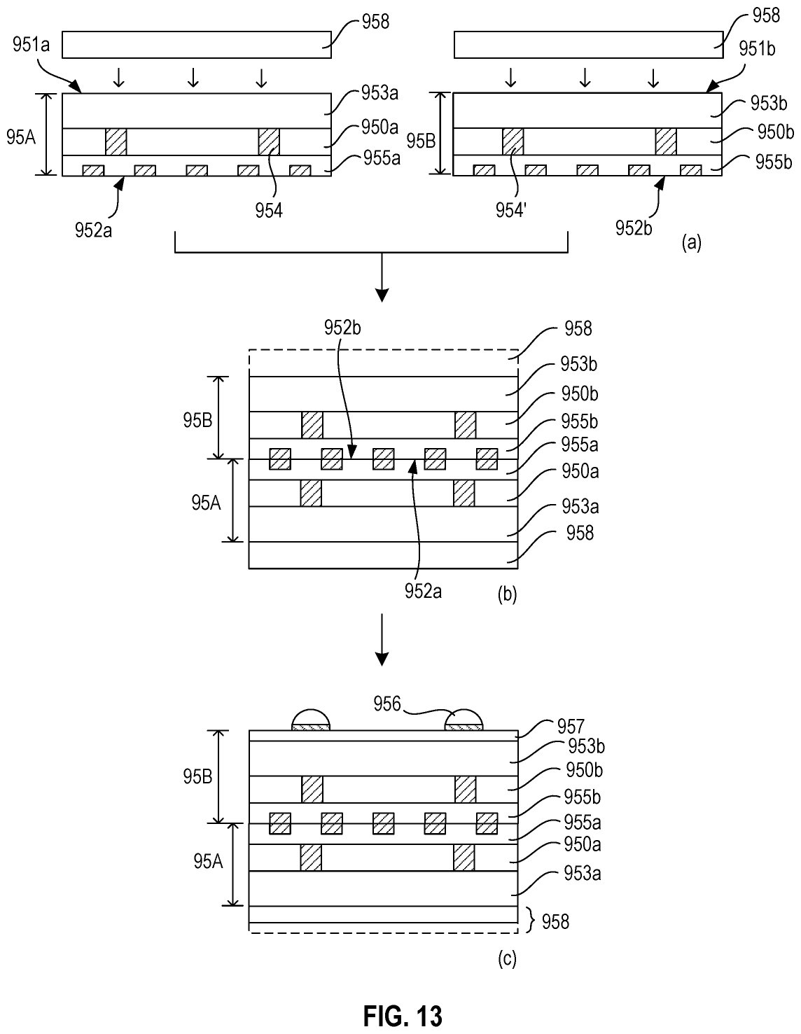

FIG. 13 illustrates the back-to-back (B2B) bonding processes using two dies as an example. Detailed descriptions of the first wafer 95A in FIG. 13 can be referred to those for its counterpart in FIG. 12 with identical numerals designating identical or equivalent components. Regarding the second wafer 95B in FIG. 13, TSVs 954′ in the silicon substrate 950b are formed using via-first or via-middle processes prior to wafer-to-wafer bonding as in the case of the first wafer, 95A. The hybrid bonding layer, 955b, is disposed over the silicon substrate 950b, and a surface, 952b, of the hybrid bonding layer 955b on the backside of the second wafer, 95B, coincides with the backside 952a of the first wafer 95A. In operation (b), the backside 952a of the first wafer 95A is hybrid bonded to the backside 952b of the second wafer 95B in a back-to-back manner. Following wafer-to-wafer bonding, the base substrate, 958, of the second wafer, 95B, is removed by grinding/thinning/etching. Structures of the hybrid bonding layers, 955a and 955b, can be referred to the previous descriptions associated with FIG. 10B and are not repeated here for brevity. The hybrid bonding layers, 955a and 955b, can be both based on either PI/Cu or oxide/Cu RDL. When PI/Cu is used, an external pressure can be applied during hybrid bonding. In operation (c), RDL 957 is formed on the silicon substrate 950b, followed by creation of surface finish/under bump metallurgy (not shown) and solder/micro-solder bumps, and thinning of base plate 958 as needed.

The embodiments shown in FIGS. 11 to 13 illustrates F2F, B2F and B2B bonding processes involving two dies. The processes described above can be repeated in a wide variety of combinations to create 3D stacking of more than two dies.

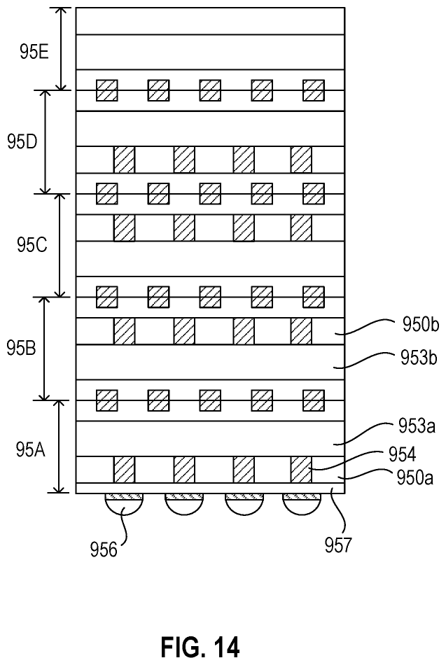

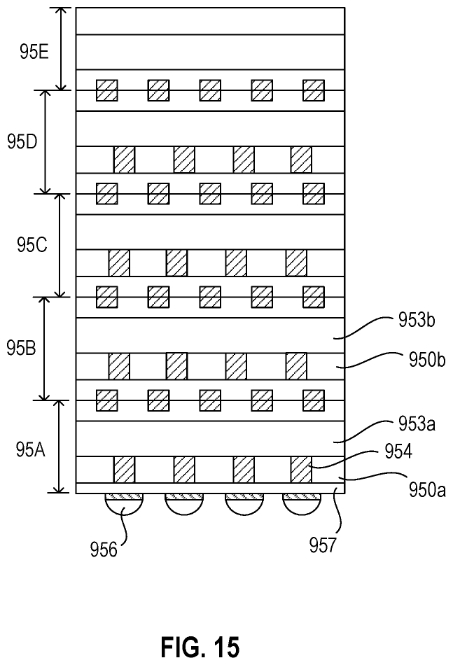

FIGS. 14 and 15 of the present disclosure present examples of 5-die stacks that can be derived from the steps and approaches depicted in FIGS. 11 to 13. As illustrates in FIG. 14, the wafers, 95A, 95B, 95C, 95D, and 95E, are bonded through hybrid bonding using a combination of F2F and B2B processes. In FIG. 15, these wafers are bonded through hybrid bonding using F2B processes. It is important to note that the approaches described herein can be extended to stacking beyond five dies.

When performing the wafer bonding process as described herein, commercially available wafer-to-wafer bonders can be used for low-temperature (e.g., room-temperature) dielectric-to-dielectric bonding. Typically, this involves using ions or neutral atoms in a vacuum to physically remove the oxide films on the dielectric surfaces of the wafers or substrates to be bonded and form dangling bonds on the surfaces, which subsequently enable direct bonding.

To achieve high wafer bonding yield when performing the wafer bonding process as described herein, the bonding surfaces can be cleaned using a fast atom beam (FAB) gun (e.g., by using argon, Ar, neutral atom beam) or ion gun (e.g., by using Ar ion) to remove the oxide film, for instance, on the wafer surface in vacuum and to create dangling bonds at the surfaces. FAB works well for Si/Si, Si/SiO₂, metals, compound semiconductors, and single crystal oxides, while an ion gun is known to work for SiO₂/SiO₂, Glass, SiN/SiN, Si/Si, Si/SiO₂, metals, compound semiconductor, and single crystal oxide. In some embodiments, a vacuum of 10⁻⁶ Pa (pascal) is required during bonding to prevent re-adsorption to activated bonding surfaces above. Additionally, a surface roughness of about 1 nm Ra (arithmetic mean surface roughness) is preferred at the surfaces of the two wafers to be bonded. This level of Ra can be achieved by chemical-mechanical polish (CMP) for silicon.

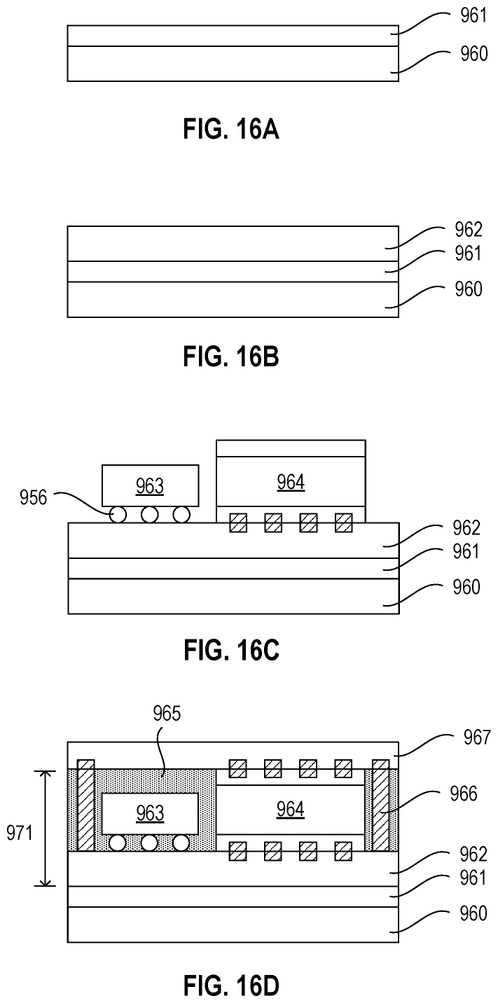

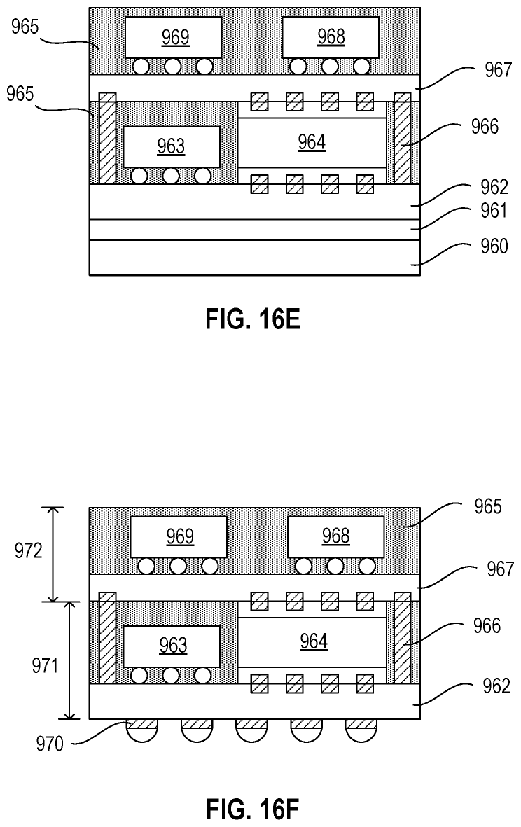

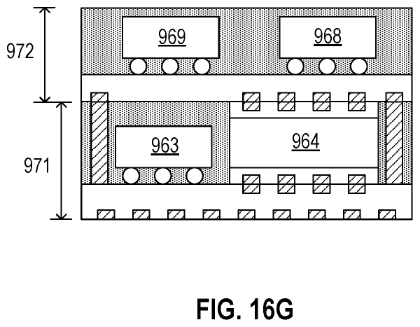

For space-constrained applications such as smart handhelds, ultra-thin, multi-die 3D IC packages can be created using fan-out processes. FIGS. 16A to 16F illustrate an embodiment of 3D IC stacking via fan-out processing. As the embodiment shown in FIGS. 16A to 16F, polyimide (PI)-to-PI hybrid bonding can be achieved based on a dielectric such as a fully cured PI derived from PMDA and ODA where PMDA stands for pyromellitic dianhydride and ODA 4, 4′-diaminodiphenyl ether with PI/Cu RDL layers on the mating surfaces under the application of an external pressure during hybrid bonding. The processes previously described in FIGS. 11 to 15 can also be used to make the 3D ICs in FIGS. 16A to 16F. Regarding PI-to-PI bonding using fully cured polyimide-to-fully cured polyimide bonding based on PMDA and ODA as an example, one can maximize the shear strength by varying conditions such as volume of water introduced, bonding time, and oxygen (02) plasma activation time. To achieve void-free PI-to-PI bonding, it is important to activate the PI surfaces by oxygen plasma activation to generate low-density hydrophilic groups on the PI surface which effectively enhances adsorption of water molecules introduced by a de-ionized water wetting process. The adsorbed water molecules, in turn, brings in considerable high-density OH (hydroxyl) groups which facilitate pre-bonding. Following PI surface activation and wetting, PI-to-PI hybrid bonding can take place at a relative low temperature of or below 250° C. for a few minutes. Neither the plasma process nor the wetting or hydration process alone can achieve good bonding. Key parameters to manipulate in order to achieve good bond yield include plasma activation time, volume of water introduced, bonding temperature and bonding time. Oxide-to-oxide hybrid bonding requires high component flatness and surface cleanliness to avoid electrical interconnection fails due to silicon dioxide's high hardness and poor deformation characteristics. Compared to the conventional oxide-to-oxide hybrid bonding, PI-to-PI bonding allows for higher surface roughness and is more tolerant of component flatness due to the low modulus and more compliant characteristics of the PIs.

Referring to operations in FIGS. 16A to 16F, a release layer 961 which can be released by, for example, laser illumination is formed on a carrier 960 as shown in FIG. 16A, where the carrier 960 can be a glass wafer. Next, a first RDL 962 is formed on the release layer 961 as shown in FIG. 16B. The first RDL 962 can include a PI/Cu hybrid bonding surface for subsequent hybrid bonding to an IC package containing a matching PI/Cu hybrid bonding surface. Besides using PI/Cu for hybrid bonding, LDT oxide/Cu can also be considered.

Referring to FIG. 16C and FIG. 16D, a die 963 is then bonded to the bonding pads on the first RDL 962 with surface finish through micro-bumps or solder bumps 956, and a first 3D IC 964 disposed laterally to the die 963 is bonded to the first RDL 962 through hybrid bonding. Subsequently, the die 963 and the first 3D IC 964 can be encapsulated by a molding compound (or a suitable encapsulation material such as a thick film photoresist which can be laminated on) 965 through molding. In some embodiments, the molding compound 965 is ground and polished (e.g., by chemical-mechanical polish) to expose the topside of the 3D IC 964 in a grinding and polishing operation, exposing electrical connections (e.g., copper pillar micro-bumps) of the 3D IC 964, or electrical connections of an electronic component with the thicker thickness. Note the die 963 and the 3D IC 964 residing in the same layer of the fan-out substrate may possess different thicknesses. In some embodiments, a plurality of through-mold vias (TMVs) 966 can be formed prior to die bonding or subsequent to the molding operation. The TMVs 966 electrically connect the first RDL 962 and the second RDL 967. Similar to the first RDL 962, the second RDL 967 may include a PI/Cu (or an oxide/Cu) hybrid bonding surface.

In some embodiments, the single-layer fan-out substrate 971 in FIG. 16D can contain more than two IC structures such as 963 and 964 in the same layer.

Referring to FIG. 16E, in some embodiments, a second 3D IC 968 and a third 3D IC 969 can be mounted over the second RDL 967. The second 3D IC 968 and the third 3D IC 969 can be encapsulated by the molding material 965 in another molding operation. The molding material 965 can be ground and polished to a desired thickness and, as needed, to expose 3D ICs, 968 and/or 969, to facilitate die cooling by attaching a heat spreader and a heatsink with the use of thermal interface materials. Then, as shown in FIG. 16F, after the stacking of the dies and/or 3D ICs, the carrier 960 and the release layer 961 are removed through a de-bonding operation (via, for example, a combination of laser illumination and wet cleaning) to expose the bottom side of the first RDL 962. In some embodiments, a plurality of bonding pads and conductive bumps (e.g., solder bumps) 970 can be formed on the first RDL 962 for external connection.

In some embodiments, the 3D structure illustrated in FIG. 16F is a dual-layer fan-out substrate (971 and 972) which can contain more dies and 3D ICs than shown. In some embodiments, a fan-out substrate with more than 2 fan-out layers can be formed as needed by repeating the processes illustrated in FIGS. 16A to 16F.

In addition, in other embodiments, referring to FIG. 16G, at least one side of the single layer fan-out substrate 971 or dual-layer fan-out substrate, 971 and 972, includes a hybrid bonding layer. The dielectric material of the hybrid bonding layer includes a PI, a back-end-of-line (BEOL) oxide with a deposition temperature preferably lower than 250° C. or a polymer with a curing temperature lower than 250° C. and a L/S capability smaller than 5 μm/5 μm.

The final fan-out multi-die package can be mounted to the next-level substrate (e.g., a laminate substrate) through micro-bumps, solder bumps or hybrid bonding.

Once the dies/3D ICs are assembled, as previously shown in FIGS. 11 to 16G, the dies/3D ICs can be mounted on a laminate substrate, or an interposer which is assembled on a laminate substrate, and the laminate substrate is subsequently bonded to a PCB for power, signal, and ground. In other words, multi-level packaging serves as the space transformer to allow power to go from the power cord of the PCB to the ultra-tiny transistors on the IC.

The present disclosure aims to provide a wide variety of 3D IC package structures that heterogeneously integrate the best L/S/pitch and bonding technologies from adjacent industries covering IC, the IC packaging and/or the substrate industries to achieve the highest function integration densities. FIG. 10C provides an example of structural and process options available covering IC, interposer, package substrate and PCB.

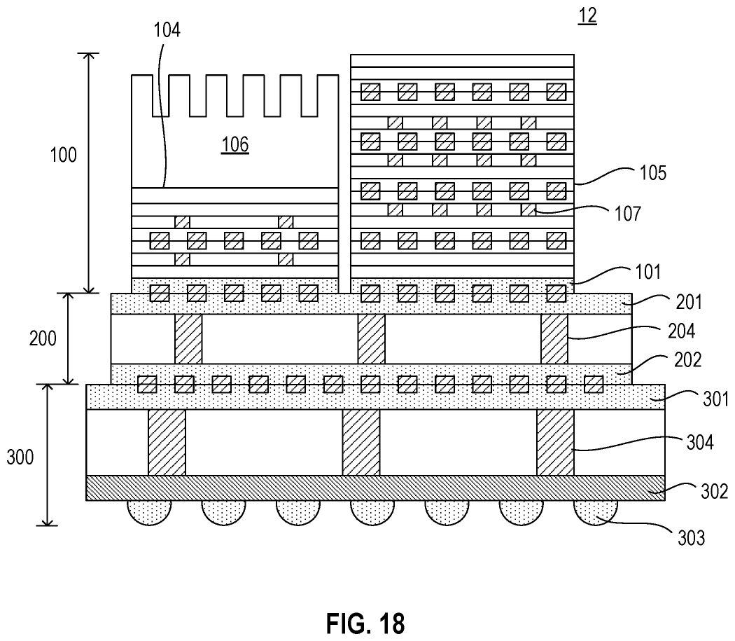

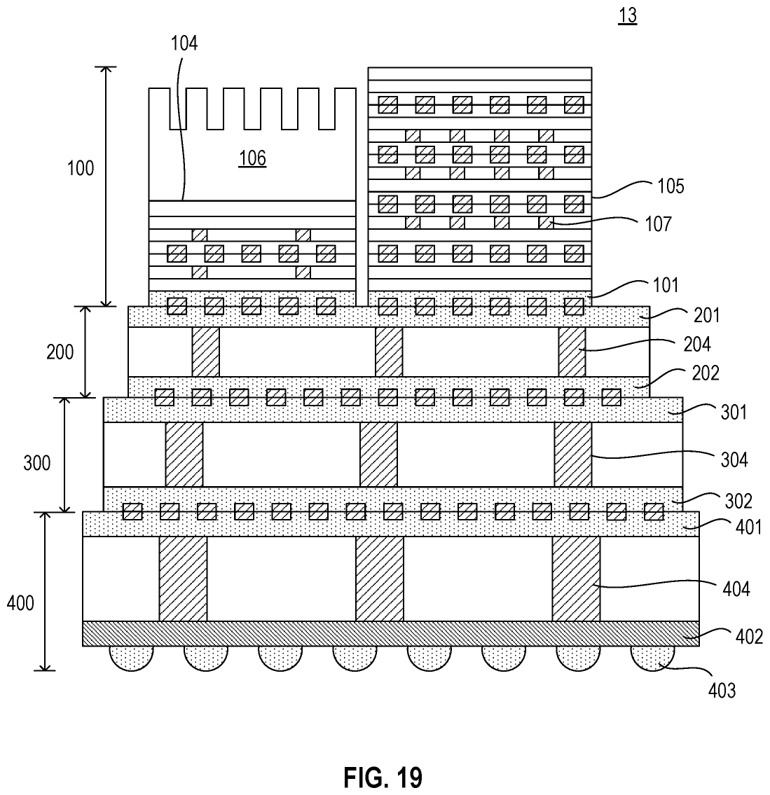

Using the assembly of a 2-die stack and a 5-die 3D IC as an example, referring to the embodiments illustrated in FIGS. 17A to 22, at least 4 novel 3D IC package structures can be assembled using the aforementioned processes for demonstration:
Structure 1: referring to FIG. 17A, (a) micro-bumps 103 and solder bumps 203, respectively, for interconnection between 3D IC 100 and interposer 200, and between interposer 200 and laminate substrate 300, and (b) PI/Cu RDL or LDT oxide/Cu RDL on one side or both sides of the interposer (e.g., interconnect layer 201 and/or 202);
Structure 2: referring to FIG. 17B, (a) oxide-to-oxide hybrid bonding (e.g., bonding of the interconnect layer 101 and the interconnect layer 201) and micro-bumps/solder bumps 203, respectively, for interconnection between 3D IC and interposer, and between interposer and laminate substrate, and (b) wafer BEOL oxide/Cu RDL on the top side of the interposer (e.g., the interconnect layer 201) for 3D IC mounting and PI/Cu RDL or LDT oxide/Cu RDL on the bottom side of the interposer (e.g., the interconnect layer 202);
Structure 3: referring to FIG. 18, (a) oxide-to-oxide hybrid bonding (e.g., bonding of the interconnect layer 101 and the interconnect layer 201) and PI-to-PI hybrid bonding (e.g., bonding of the interconnect layer 202 and the interconnect layer 301; or LDT oxide-to-LDT oxide), for interconnection between 3D IC and interposer, and between interposer and laminate substrate, respectively, and (b) wafer BEOL oxide/Cu RDL (e.g., the interconnect layer 201) on the top side of the interposer for oxide-to-oxide hybrid bonding, and PI/Cu RDL (e.g., the interconnect layer 202; or LDT oxide/Cu RDL) on both the bottom side of the interposer and the top side of the laminate substrate (e.g., the interconnect layer 301) for PI-to-PI hybrid bonding; and
Structure 4: referring to FIG. 19, application of interposer-to-laminate substrate bonding processes based on PI/Cu (or LDT oxide/Cu) to the bonding of the laminate substrate to the PCB again based on PI/Cu.

The embodiments described herein includes configurations of one or more IC blocks, one or more interposers, one or more laminate substrates or package substrates, one or more PCBs. Each of the IC blocks, interposers, laminate substrates, package substrates, or PCBs possesses respective interconnect layers configured to form electrical (and optical) connections to one another, to embedded devices, to passive devices, to optical devices, and/or to other adjoining electronic components. Material and structural options of the components and interconnect layers described herein can at least be selected from those associated with the Figures disclosed herein

Referring to FIG. 17A, the semiconductor package 10 includes an integrated circuit (IC) block 100 and a first substrate 200 supporting or carrying the IC block 100. The IC block 100 has a first interconnect layer 101 facing a second interconnect layer 201 of the first substrate 200. The IC block 100 includes at least a semiconductor die, a die stack or a chip structure, such as the 3D IC described herein, for example, the 3D IC stacks in FIG. 11 to FIG. 16G. In some embodiments, the IC block 100 includes a plurality of ICs or IC structures. In some embodiments, at least two of the ICs or IC structures are hybrid bonded with respective inorganic-conductive hybrid or organic-conductive hybrid bonding layers. In some embodiments, at least one IC or IC structure includes a plurality of first through vias 107. In the embodiment shown in FIG. 17A, the IC block 100 includes a 2-die stack 104 and an adjacent 5-die 3D IC 105. The 2-die stack 104 and/or the 3D IC 105 can be attached with a heat sink/heat spreader 106 using thermal interface materials, which is designed to efficiently transfer the heat generated by the stacked dies beneath it. Examples of the processes to fabricate the 2-die stack 104 and the 5-die 3D IC 105 can be seen in the embodiments associated with FIGS. 11 to 15.

In some embodiments, the first interconnect layer 101 is located on one side of the IC block 100 for external connections. The first interconnect layer 101 is composed of a dielectric material and a conductive material which can be oxide/Cu RDL or PI/Cu RDL for flip chip connection to the first substrate 200. Alternatively, in some embodiments, the first interconnect layer 101 is composed of a dielectric material and a conductive material which can include oxide/Cu RDL adhesive or PI/Cu RDL for hybrid bonding (not illustrated in FIG. 17A) to a first substrate 200. In some embodiments, the L/S of the first interconnect layer 101 can be smaller than 2 μm/2 μm with a thickness of which being about 5 μm. In some embodiments, the L/S of the first interconnect layer 101 can be smaller than 1 μm/1 μm. In some embodiments where the solder-containing terminal is implemented, a plurality of solder bumps such as micro-bumps 103 form electrical connection between the first interconnect layer 101 and the second interconnect layer 201. In some embodiments, the bonding pitch of the plurality of micro-bumps 103 connecting the IC block 100 and first substrate 200 can be about 40 μm.

The IC block 100 is supported by the first substrate 200. In some embodiments, the first substrate 200 includes two interconnect layers on the two sides of the substrate for electrical connections. As illustrated in FIG. 17A, the first substrate 200 may include a second interconnect layer 201 facing the first interconnect layer 101, and a third interconnect layer 202 opposite to the second interconnect layer 201.

In some embodiments, the first substrate 200 is an interposer. In some embodiments, each of the second interconnect layer 201 and the third interconnect layer 202 is composed of a dielectric material and a conductive material. In some embodiments, at least one of the second interconnect layer 201 or the third interconnect layer 202 is composed of a dielectric material and a conductive material (which can include PI/Cu RDL or oxide/Cu RDL) substantially identical to a corresponding dielectric material and a corresponding conductive material of the first interconnect layer 101. In some embodiments, both the second interconnect layer 201 and the third interconnect layer 202 include PI/Cu RDL or oxide/Cu RDL. The PI/Cu RDL or the oxide/Cu RDL of the third interconnect layer 202 can form electrical connections through a plurality of solder bumps 203 to a second substrate 300. In some embodiments, the dielectric of the second interconnect layer 201 can be a back-end-of-line (BEOL) oxide with a deposition temperature lower than 250° C. or a polymer with a curing temperature lower than 250° C. and a line width/line spacing (L/S) smaller than 5 μm/5 μm. In some embodiments, the dielectric of the third interconnect layer 202 can be a polymer with a L/S smaller than 5 μm/5 μm or a BEOL oxide. In some embodiments, the bond pitch of the plurality of solder bumps 203 connecting the first substrate 200 and the second substrate 300 can be about 100 μm-400 μm.

In some embodiments, the first substrate 200 is fan-out substrate. The fan-out substrate can be referred to previous description associated with FIG. 16A to FIG. 16G but not limited thereto. In some embodiments, the dielectric of the second interconnect layer 201 can be a back-end-of-line (BEOL) oxide with a deposition temperature lower than 250° C. or a polymer with a curing temperature lower than 250° C. and a line width/line spacing (L/S) smaller than 5 μm/5 μm. In some embodiments, the dielectric of the third interconnect layer 202 can be a polymer with a curing temperature lower than 250° C. and a L/S smaller than 5 μm/5 μm or a BEOL oxide with a deposition temperature lower than 250° C.

In some embodiments, one or more active devices (e.g., see FIG. 7), passive devices (e.g., see FIG. 9), and/or optical devices (e.g., see FIG. 23A and FIG. 23B) can be integrated or embedded in the second interconnect layer 201 and/or the third interconnect layer 202 of the first substrate 200 or inside the first substrate supporting the IC block 100. Similarly, when the first substrate 200 is a fan-out substrate, the one or more active devices (e.g., see FIG. 7), passive devices (e.g., see FIG. 9), and/or optical devices (e.g., see FIG. 23A and FIG. 23B) can be integrated or embedded in the fan-out substrate, or the structure (e.g., molding layer) between the second interconnect layer 201 and the third interconnect layer 202.

In some embodiment, the first substrate 200 may include a plurality of second through vias 204 electrically connecting the second interconnect layer 201 and the third interconnect layer 202, wherein a pitch of the second through vias 204 is equal to or different from a pitch of the first through vias 107. For example, the first through vias 107, can be the through vias (954 and 954′) described in FIG. 11 to FIG. 15, and the second through vias 204 can be the through vias 935 described in FIG. 8. In some embodiments, a diameter of the first through vias 107 in the individual IC die or IC structure can be from 2 μm to 6 μm with a pith of which being from 4 μm to 15 μm, and a depth of which being from 25 μm to 30 μm. In some embodiments, a diameter of the second through vias 204 of first substrate 200 can be from 5 μm to 20 μm with a pitch of which being from 10 μm to 40 μm and a depth of which being from 25 μm to 100 μm.

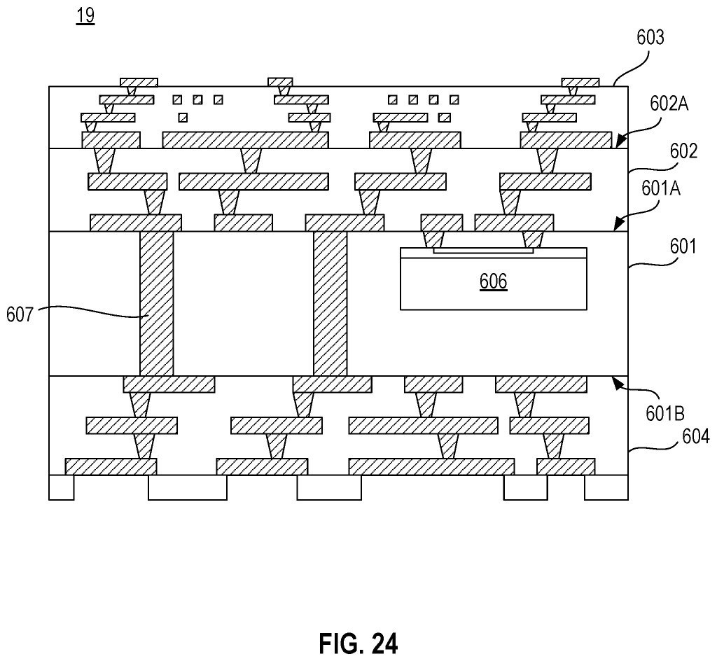

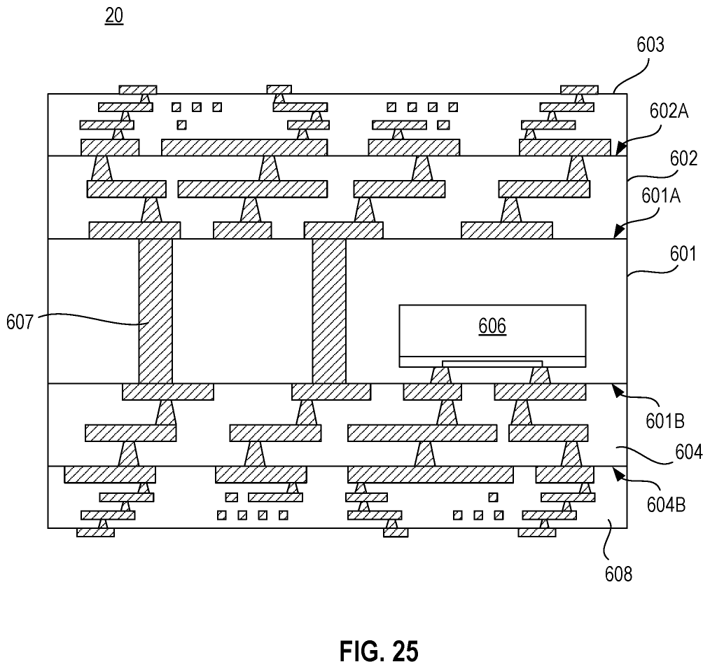

Still referring to FIG. 17A, the semiconductor package 10 further includes a second substrate 300 supporting the first substrate 200. In some embodiments, the second substrate 300 is a packaging substrate, such as a laminate substrate described herein, for example, the laminate substrates in FIG. 8, FIG. 25, and FIG. 24. The second substrate 300 may include a fourth interconnect layer 301 facing the third interconnect layer 202. In some embodiments, the fourth interconnect layer 301 can include ABF/Cu RDL, which is different from those used in forming the second interconnect layer 201 and the third interconnect layer 202 in terms of L/S/pitch capabilities. In some embodiments, the L/S of the fourth interconnect layer 301 composed of ABF/Cu RDL can be about 6 μm/6 μm, and a thickness of which can be about 20 μm.

In some embodiments, the second substrate 300 may further include a fifth interconnect layer 302 opposite to the fourth interconnect layer 301 in the second substrate 300. In some embodiments, the fifth interconnect layer 302 may include ABF/Cu RDL similar to that in the fourth interconnect layer 301 but with different L/S and pitch. In some embodiments, the fifth interconnect layer 302 forms electrical connection with a plurality of BGA balls 303 for further external connections.

In some embodiments, the second substrate 300 may include a plurality of third through vias 304 electrically connecting a fourth interconnect layer 301 and a fifth interconnect layer 302, wherein a pitch of the first through vias 107 and a pitch of the second through vias 204 are equal to or different from a pitch of the third through vias 304. In some embodiments, the L/S of the third through vias 304 can be about 30 μm with a thickness of which being 60 μm and a depth of which being 400 μm. In some embodiments, the third through vias 304 are plated through hole (PTH) as previously described in FIG. 8.

Referring to FIG. 17B, the semiconductor package 11 includes an IC block 100 and a first substrate 200 supporting or carrying the IC block 100. Identical numerals in the IC block 100 of FIG. 17B are identical or equivalent to those described in FIG. 17A and are not repeated here for brevity. Specifically, the connections between the IC block 100 and the first substrate 200 are achieved by hybrid bonding. As depicted in FIG. 17B, the first interconnect layer 101 is under the die or the IC structure (i.e., the 2-die stack 104 and the 5-die 3D IC 105). The first interconnect layer 101 includes oxide/Cu RDL/adhesive or PI/Cu RDL/adhesive structure for hybrid bonding with the first substrate 200. Correspondingly, the second interconnect layer 201 of the first substrate 200 also includes a similar oxide/Cu RDL/adhesive or PI/Cu RDL/adhesive structure. The bonding options between the first substrate 200 and the second substrate 300 can be based on micro-bumps, solder bumps and even hybrid bonding structures, depending on the specific L/S and pitch requirements. The numerals labeling the first substrate 200 and second substrate 300 of FIG. 17B are identical or equivalent to those described in FIG. 17A and are not repeated here for brevity. For example, the first substrate 200 in FIG. 17B can be an interposer or a fan-out substrate.

In some embodiments, at least one of the second interconnect layer 201 or the third interconnect layer 202 is composed of a dielectric material and a conductive material substantially identical to a corresponding dielectric material and a corresponding conductive material of the fourth interconnect layer 301. For instance, the interposer and the packaging substrate (e.g., the laminated substrate) can be bonded through hybrid bonding, as illustrated in FIG. 18.

Referring to FIG. 18, in other embodiments, the fourth interconnect layer 301 in a semiconductor package 12 may include PI/Cu RDL/adhesive (or LDT oxide/Cu) structure for hybrid bonding with the first substrate 200, and therefore, not only are the first interconnect layer 101 and the second interconnect layer 201 solderlessly bonded, but also the third interconnect layer 202 and the fourth interconnect layer 301 are solderlessly bonded.

Also, it is also shown in FIG. 18 that in some embodiments, the third interconnect layer 202 and the fourth interconnect layer 301 are hybrid bonded via organic-conductive or inorganic-conductive hybrid bonding layers.

Referring to a semiconductor package 13 shown in FIG. 19, the IC block 100, the first substrate 200, and the second substrate 300 are supported by a third substrate 400. In some embodiments, the third substrate 400 is a PCB. In some embodiments, the third substrate 400 may include a plurality of fourth through vias 404 electrically connecting a sixth interconnect layer 401 and a seventh interconnect layer 402, wherein a pitch of the first through vias 107, a pitch of the second through vias 204, and a pitch the third through vias 304 are equal to or different from a pitch of the fourth through vias 404. In some embodiments when the third substrate 400 is a PCB, the fourth through vias 404 can be a plated through holes (PTH). The sixth interconnect layer 401 and the seventh interconnect layer 402 are located at the two opposite sides of the third substrate 400. In some embodiments, the sixth interconnect layer 401 may include PI/Cu (or LDT oxide/Cu) structure for hybrid bonding to the fifth interconnect layer 302 of the second substrate 300 containing a matching PI/Cu structure. The seventh interconnect layer 402 rely on a plurality of BGA balls 403 for external connections.

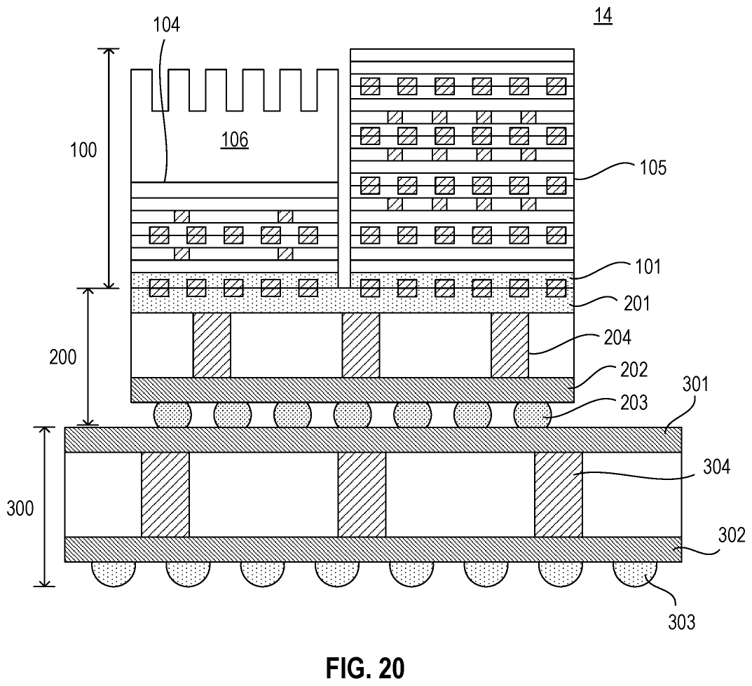

Referring to a semiconductor package 14 shown in FIG. 20, the IC block 100, and the first substrate 200 which may be a laminate substrate described herein, are supported by the second substrate 300, which may be a PCB described herein. In such embodiments, the first interconnect layer 101 and the second interconnect layer 201 may include oxide/Cu or PI/Cu configured for hybrid bonding, and the third interconnect layer 202 and fourth interconnect layer 301 may include ABF/Cu RDL to form electrical connections based on solder bumps 203. The fifth interconnect layer 302 may include ABF/Cu RDL to form electrical connections using solder bumps or BGA balls 303.

In other embodiments, a dielectric material of the second interconnect layer 201 of the first substrate 200 (e.g., a laminate substrate) of the semiconductor package 14 in FIG. 20 can be composed of back-end-of-line (BEOL) oxide with a deposition temperature lower than 250° C. or a polymer with a curing temperature lower than 250° C. and a line width/line spacing (L/S) smaller than 5 μm/5 μm, and a dielectric material of the third interconnect layer 202 of the first substrate 200 (e.g., a laminate substrate) can be composed of a polymer with a curing temperature lower than 250° C. and a L/S smaller than 5 μm/5 μm or a build-up film.

In other embodiments, the first substrate 200 of the semiconductor package 14 in FIG. 20 is a laminate substrate having a core layer 601, build-up layers (602 and 604), and repassivation layers (603 and 608) as subsequently described in FIG. 24 and FIG. 25. People having ordinary skill in the art can refer thereto for details of the laminate substrate implemented in the semiconductor package 14 of FIG. 20.

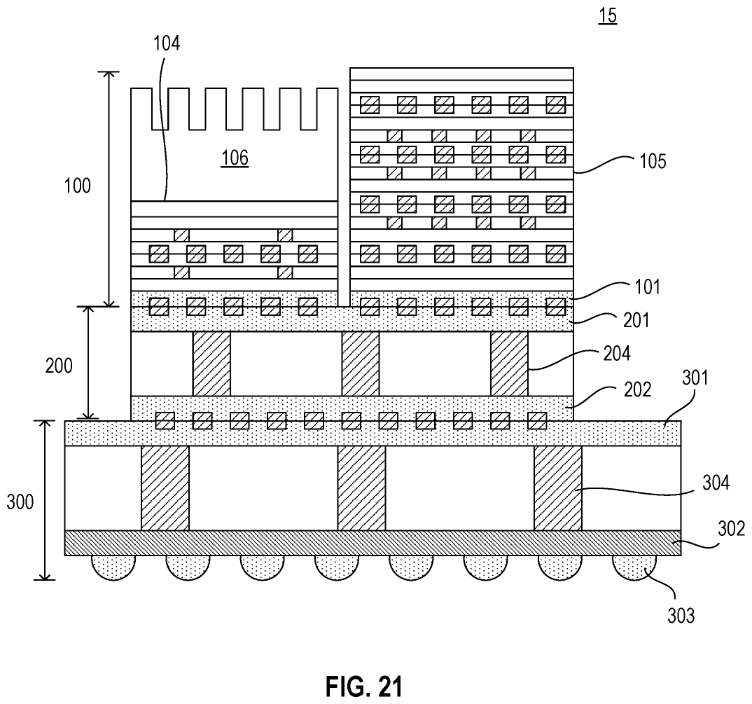

Referring to a semiconductor package 15 shown in FIG. 21, alternatively, in some embodiments, the IC block 100, and the first substrate 200 which may be a laminate substrate and is mounted on the second substrate 300 such as a PCB through hybrid bonding. In such embodiment, the first interconnect layer 101 and the second interconnect layer 201 may include oxide/Cu or PI/Cu configured for hybrid bonding, and both the third interconnect layer 202 and the fourth interconnect layer 301 may include PI/Cu (or LDT oxide/Cu) structures for hybrid bonding the first substrate 200 to the second substrate 300. The fifth interconnect layer 302 may include ABF/Cu RDL to form electrical connections using solder bumps or BGA balls 303 to the next-level substrate.

Similar to those described in FIG. 20, a dielectric material of the second interconnect layer 201 of the first substrate 200 (e.g., a laminate substrate) in FIG. 21 can be composed of back-end-of-line (BEOL) oxide with a deposition temperature lower than 250° C. or a polymer with a curing temperature lower than 250° C. and a line width/line spacing (L/S) smaller than 5 μm/5 μm, and a dielectric material of the third interconnect layer 202 of the first substrate 200 (e.g., a laminate substrate) can be composed of a polymer with a curing temperature lower than 250° C. and a L/S smaller than 5 μm/5 μm or a build-up film.

In other embodiments, the first substrate 200 of the semiconductor package 15 of FIG. 21 is a laminate substrate having a core layer 601, build-up layers (602 and 604), and repassivation layers (603 and 608) as subsequently described in FIG. 24 and FIG. 25. People having ordinary skill in the art can refer thereto for details of the laminate substrate implemented in the semiconductor package 14 of FIG. 20.

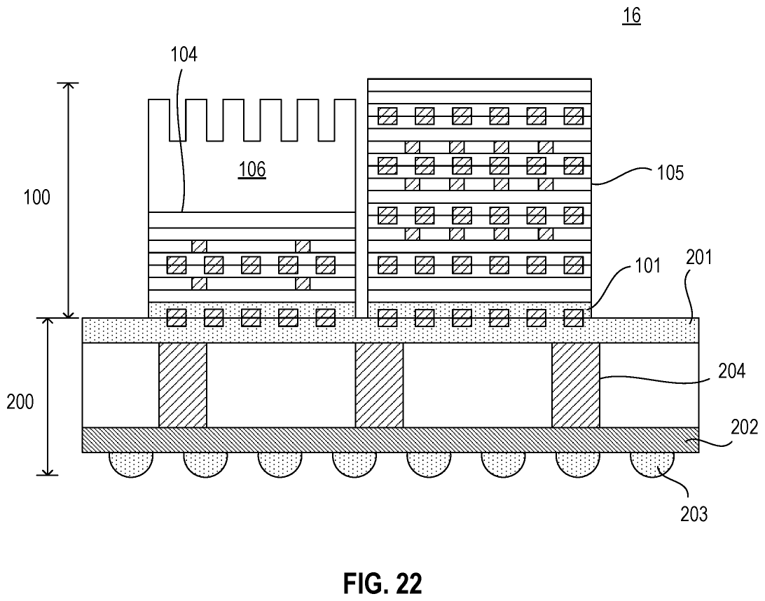

Referring to a semiconductor package 16 shown in FIG. 22, in some embodiments, the IC block 100 can be supported by the first substrate 200 which can be a PCB. In such embodiments, the first interconnect layer 101 of the IC block 100 and the second interconnect layer 201 of the first substrate can include PI/Cu or LDT oxide/Cu structure for hybrid bonding the IC block 100 to the first substrate 200. The third interconnect layer 202 may include ABF/Cu RDL to form electrical connections using solder bumps or BGA balls 303 to the next-level substrate.

In some embodiments, the dielectric material of the second interconnect layer 201 of the first substrate 200 in FIG. 24 can be composed of a back-end-of-line (BEOL) oxide with a deposition temperature lower than 250° C. or a polymer with a curing temperature lower than 250° C. and a line width/line spacing (L/S) smaller than 5 μm/5 μm. In some embodiments, the dielectric material of the third interconnect layer 202 of the first substrate 200 in FIG. 24 can be composed of a polymer with a curing temperature lower than 250° C. and a L/S smaller than 5 μm/5 μm or a build-up film as the second dielectric.

In the aforementioned embodiments associated with FIGS. 17A-22, the terms regarding the first substrate 200, the second substrate 300, and the third substrate 400 are used for describing the interposer, the laminated substrate (or the packaging substrate), and the PCB for demonstration purposes. Other combinations of substrate options also exist.

The methodologies, processes, and structures described in the present disclosure can be applied to a wide variety of other advanced SiP styles as appropriate. An example of such application is depicted in FIGS. 23A and 23B where the semiconductor packages 17 and 18 represent co-packaging of silicon photonics with application-specific IC (ASIC)/FPGA/CPU in two different package configurations: one based on solder bonding (FIG. 23A) and the other on hybrid bonding (FIG. 23B).

As shown in FIG. 23A, a carrier 506 (which can be a laminate substrate or a silicon interposer) is mounted with an active device 501 such as ASIC, FPGA, CPU, or the like. Besides the active device 501, an optical module 502 which is bonded to a silicon interposer 503, or on the first substrate receiving a photonic IC block described herein, can be mounted on the carrier 506. In some embodiments, an optical fiber 504 coupling optical signal into or out from a waveguide structure 508 is optically connected to the optical module 502. Although not illustrated in FIG. 23A, at least one electrical-to-optical conversion component or optical-to-electrical conversion component is embedded or integrated in the silicon interposer 503 and/or the waveguide structure 508. In some embodiments, both the active device 501 and the silicon interposer 503 are mounted over the carrier 506 through a plurality of solder bumps 507 (or micro-bumps as needed).

Referring to FIG. 23B, similar to the components described in FIG. 23A, one side of the active device 501 (e.g., a side 501A) and one side of the silicon interposer 503 (e.g., a side 503A) can include an interconnection layer having an LDT oxide/Cu or PI/Cu structure for hybrid bonding to a corresponding interconnect layer of the carrier 506 (e.g., at a side 506A). In some embodiments, another side of the carrier 506 may include a plurality of BGA balls for external connections.

As disclosed in FIGS. 23A and 23B, silicon photonics modules mounted over an optical waveguide-containing silicon interposer can be bonded to either a high-density laminate substrate or another silicon interposer, while the silicon interposer 503 and the laminate substrate 506 are bonded together using oxide-to-oxide or PI-to-PI hybrid bonding.

The methodologies, processes, and structures can also be extended to include the embedding of passive devices, such as silicon interconnects and/or active devices, using embedding passive devices or active devices in laminate substrate as an example. Referring to the semiconductor package shown in FIG. 24, in some embodiments, a laminate substrate 19 can include a core 601 (or a core section), and a pre-preg wiring layer stack having a minimal L/S greater than 10 μm/10 μm. The core 601 can be prepared by stacking or laminating pre-punched pre-preg (e.g., BT/glass) layers around a passive device or an active device 606. In some embodiments, an optical device can be embedded in the core 601 in the same manner as the passive or active device 606. Through holes can be formed in the pre-preg layer stack by a laser drilling operation or a mechanical drilling operation as needed, to form through vias 607 connecting the top surface 601A and the bottom surface 601B of the core 601. The through vias 607 and their electrical connections proximal to the top surface 601A and the bottom surface 601B can be formed by at least one of the following operations: desmear, copper plating (electrical or electroless), photoresist formation and removal, thin copper deposition and etching.

Referring to FIG. 24, a first build-up wiring layer 602 over a top surface 601A of the core 601 may have a minimal L/S between 6 μm/6 μm and 10 μm/10 μm. A first repassivation wiring layer 603 over a top surface 602A of the first build-up wiring layer 602 may have a minimal L/S equal to or smaller than 2 μm/2 μm. In some embodiments, the repassivation wiring layers 603 in the present disclosure may feature ultrafine pitch. The first build-up wiring layer 602 can be formed by adopting at least one of the following operations: ABF deposition, via formation by laser drilling, desmear, thin copper deposition, photoresist deposition, patterning, and removal, copper plating (electrical or electrode-less), and thin copper etching. The operations set forth can be repeated to achieve desired number of layers or total thickness in the first build-up wiring layer 602. By the same token, the second build-up wiring layer 604 can be fabricated. The outermost surface of the second build-up wiring layer 604 is then attached to a temporary carrier (e.g., a glass carrier) via a release/adhesive layer for subsequent fabrication of the first repassivation wiring layer 603.

In some embodiments, the first repassivation wiring layer 603 is composed of PI/Cu or oxide/Cu, forming a first interconnect layer configured to be bonded to an IC block or a substrate. In some embodiments, the first repassivation wiring layer 603 includes an organic-conductive hybrid bonding layer or an inorganic-conductive hybrid bonding layer. When PI is used as the dielectric, the formation of the first repassivation wiring layer 603 may include at least one of the following operations: PI deposition, oxide deposition, seed layer deposition, conductive trace definition, copper electroplating, photoresist strip and thin copper etching. The operations set forth can be repeated to achieve desired number of layers or total thickness in the first repassivation wiring layer 603. Optionally, formation of solder mask and metal surface finish (e.g., gold, nickel, etc.) can be performed at the outermost surface of the first repassivation wiring layer 603 to facilitate subsequent assembly with the IC block or a substrate. The temporary carrier (e.g., a glass carrier) can then be removed, after the formation of the first repassivation wiring layer 603 at the last stage of embedded laminate substrate formation. In some embodiments, the first repassivation wiring layer 603 can serve as the second interconnect layer, the third interconnect layer, the fourth interconnect layer, or the fifth interconnect layer described herein, and the laminate substrate 19 can serve as the first substrate, the second substrate, the third substrate, or the fourth substrate described herein

Moreover, regarding another side of the core 601, as shown in FIG. 24, in some embodiments, the laminate substrate 19 may further include a second build-up wiring layer 604 under a bottom surface 601B of the core 601. The first and the second build-up wiring layers 602, 604 can be electrically connected through the PTHs 607 penetrating the core 601.

Referring to FIG. 24, the varying pitch scale along the vertical direction of the laminate substrate 19 allows for the accommodation of different device sizes and configurations to optimize the overall design and functionality in support of 3D ICs. In some embodiments, there can be a plurality of pre-preg wiring layers embedding at least a passive device, an active device, or an optical component.

Referring to FIG. 25, in some embodiments, both sides of the core 601 can have their respective repassivation wiring layers, as shown in the laminate substrate 20. A second repassivation wiring layer 608 is under a bottom surface 604B of the second build-up wiring layer 604 with the second repassivation wiring layer 608 having a L/S that is identical to or different from the L/S of the first repassivation wiring layer 603. The manufacturing processes to form the substrate structure in FIG. 25 are similar to those described for FIG. 24 and are not repeated here for brevity. For the laminate substrate 20 of FIG. 25, a second temporary carrier (e.g., glass carrier) may be bonded to the first repassivation wiring layer 603 formed in previous operations to provide mechanical support. The second carrier is released therefrom after the formation of the second repassivation wiring layer 608.

Going forward, the trend of traditional interconnect scaling and feature size miniaturization will continue in the IC, interposer, IC substrate, IC packaging, and PCB industries, as it has over the past several decades since the inception of microelectronics. The methodologies, processes, and structures in the present disclosure will empower these industries to leverage the finest and most advanced capabilities from adjacent industries as time progresses. The methodologies, processes and structures will help speed up the scaling of 3D IC stacking, interposer, IC substrate, and 3D IC packaging technologies at a faster pace than what can be achieved through traditional scaling methods alone and enable continuation of heterogeneous integration of mainstream finer L/S/pitch technologies from adjacent industries.

The foregoing outlines structures of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
an integrated circuit (IC) block having a first interconnect layer; and
a first substrate carrying the IC block, comprising:
a second interconnect layer facing the first interconnect layer; and
a third interconnect layer opposite to the second interconnect layer,
wherein at least one of the second interconnect layer or the third interconnect layer is composed of a dielectric material and a conductive material substantially identical to a corresponding dielectric material and a corresponding conductive material of the first interconnect layer.

2. The semiconductor package of claim 1, further comprising a second substrate carrying the IC block and the first substrate, comprising a fourth interconnect layer facing the third interconnect layer, wherein at least one of the second interconnect layer or the third interconnect layer is composed of a dielectric material and a conductive material substantially identical to a corresponding dielectric material and a corresponding conductive material of the fourth interconnect layer.

3. The semiconductor package of claim 2, wherein the first interconnect layer and the second interconnect layer are solderlessly bonded, and wherein the third interconnect layer and the fourth interconnect layer are solderlessly bonded.

4. The semiconductor package of claim 3, wherein the third interconnect layer and the fourth interconnect layer are hybrid bonded via organic-conductive hybrid bonding layers.

5. The semiconductor package of claim 1, wherein the first interconnect layer is a hybrid bonding layer, and the second interconnect layer is a hybrid bonding layer.

6. The semiconductor package of claim 5, wherein the first substrate is a laminate substrate or a printed circuit board.

7. The semiconductor package of claim 6, wherein the first substrate comprises:
a pre-preg wiring layer;
a build-up wiring layer stacked over the pre-preg wiring layer, having a finer pitch and a finer line width than those of the pre-preg wiring layer; and
a repassivation wiring layer over the build-up wiring layer, having a finer pitch and a finer line width than those of the build-up wiring layer,
wherein the repassivation wiring layer comprises an organic-conductive hybrid bonding layer or an inorganic-conductive hybrid bonding layer.

8. The semiconductor package of claim 7, further comprising a plurality of pre-preg wiring layers embedding at least a passive device, an active device, or an optical component.

9. The semiconductor package of claim 1, further comprising at least an active device, a passive device or an optical component integrated in at least one of the second interconnect layer, the third interconnect layer or the structure in between the second and the third interconnect layers of the first substrate.

10. The semiconductor package of claim 1, wherein the IC block comprises a plurality of ICs arranged in a multi-layer fan-out structure with the multi-layer fan-out structure comprising:
at least a first IC and a second IC in a first fan-out carrier; and
at least a second fan-out carrier comprising at least a third IC over the first fan-out carrier,
wherein at least one side of the first fan-out carrier or at least one side of the second fan-out carrier comprises a hybrid bonding layer having, as the dielectric, a back-end-of-line (BEOL) oxide with a deposition temperature lower than 250° C. or a polymer with a curing temperature lower than 250° C. and a line width/line spacing (L/S) smaller than 5 μm/5 μm.

11. A semiconductor package, comprising:
a first substrate, including:
a first interconnect layer configured for hybrid bonding to an integrated circuit (IC) block or a second substrate with the first interconnect layer comprising a first dielectric and a first line width; and
a second interconnect layer opposite to the first interconnect layer with the second interconnect layer comprising a second dielectric and a second line width,
wherein the first dielectric is identical to or different from the second dielectric, and the first line width is identical to or different from the second line width.

12. The semiconductor package of claim 11, wherein the first substrate is an interposer with (1) a back-end-of-line (BEOL) oxide or a polymer with a line width/line spacing (L/S) smaller than 5 μm/5 μm as the first dielectric and (2) a polymer with a L/S smaller than 5 μm/5 μm or a BEOL oxide as the second dielectric.

13. The semiconductor package of claim 11, wherein the first substrate is a laminate substrate with (1) a back-end-of-line (BEOL) oxide with a deposition temperature lower than 250° C. or a polymer with a curing temperature lower than 250° C. and a line width/line spacing (L/S) smaller than 5 μm/5 μm as the first dielectric and (2) a polymer with a curing temperature lower than 250° C. and a L/S smaller than 5 μm/5 μm or a build-up film as the second dielectric.

14. The semiconductor package of claim 11, wherein the first substrate is a fan-out substrate with (1) a back-end-of-line (BEOL) oxide with a deposition temperature lower than 250° C. or a polymer with a curing temperature lower than 250° C. and a line width/line spacing (L/S) smaller than 5 μm/5 μm as the first dielectric and (2) a polymer with a curing temperature lower than 250° C. and a L/S smaller than 5 μm/5 μm or a BEOL oxide with a deposition temperature lower than 250° C. as the second dielectric.

15. The semiconductor package of claim 13, wherein the first substrate further comprises:
a core section permitting accommodation of a passive device or an active device;
a build-up section stacked over the core section, having a finer pitch and a finer line width than those of the core section; and
a repassivation section over the build-up section, having a finer pitch and a finer line width than those of the build-up section,
wherein an outermost layer of the repassivation section forms the first interconnect layer.

16. The semiconductor package of claim 15, wherein the core section of the first substrate further comprises a plated through hole electrically connecting the first interconnect layer and the second interconnect layer.

17. The semiconductor package of claim 11, wherein the first substrate is a printed circuit board with (1) a back-end-of-line (BEOL) oxide with a deposition temperature lower than 250° C. or a polymer with a curing temperature lower than 250° C. and a line width/line spacing (L/S) smaller than 5 μm/5 μm as the first dielectric and (2) a polymer with a curing temperature lower than 250° C. and a L/S smaller than 5 μm/5 μm or a build-up film as the second dielectric.

18. A semiconductor package, comprising:
a first substrate, comprising:
a pre-preg wiring layer having a minimal line width/line spacing (L/S) greater than 10 μm/10 μm;
a first build-up wiring layer over a top surface of the pre-preg wiring layer, having a minimal L/S between 6 μm/6 μm and 10 μm/10 μm; and
a first repassivation wiring layer over a top surface of the first build-up wiring layer, having a minimal L/S equal to or smaller than 2 μm/2 μm,
wherein the first repassivation wiring layer is composed of a polyimide or an oxide, forming a first interconnect layer configured to bond to an integrated circuit (IC) block or another substrate.

19. The semiconductor package of claim 18, further comprising:
a second build-up wiring layer under a bottom surface of the pre-preg wiring layer; and
a second repassivation wiring layer under a bottom surface of the second build-up wiring layer with the second repassivation wiring layer having a L/S that is identical to or different from the L/S of the first repassivation wiring layer, and forming a second interconnect layer configured for bonding to another substrate.

20. The semiconductor package of claim 19, wherein the first interconnect layer and the second interconnect layer are both hybrid bonding layers.
